(19) United States
(12) Patent Application Publication
(10) Pub. No.: US 2025/0081681 A1
(43) Pub. Date: Mar. 6, 2025

(54) DISPLAY DEVICE

(71) Applicant: Samsung Display Co., LTD., Yongin-si (KR)

(72) Inventors: Ki Seong SEO, Yongin-si (KR); Min Chul SHIN, Yongin-si (KR); Ki Chang EOM, Yongin-si (KR); So Yeon YOON, Yongin-si (KR); Gwang Geun LEE, Yongin-si (KR); Yu Jin LEE, Yongin-si (KR); Jung An LEE, Yongin-si (KR)

(21) Appl. No.: 18/812,766

(22) Filed: Aug. 22, 2024

(30) Foreign Application Priority Data
Aug. 28, 2023 (KR) 10-2023-0112629

(51) Int. Cl. H01L 33/46; H01L 23/48; H01L 33/10; H01L 33/50

(52) U.S. Cl. CPC H10H 20/841; H01L 23/481; H10H 20/814; H10H 20/8512; H10H 20/882

(57) ABSTRACT

A display device includes a pixel electrode on a substrate, a bank layer on the substrate and the pixel electrode and dividing a light emitting area and a light non-emitting area, light emitting elements on the pixel electrode and including a first semiconductor layer, a second semiconductor layer, and an active layer between the first and second semiconductor layers, a first via layer on the pixel electrode and around sides of the light emitting elements, a common electrode on the first via layer, a side of a light emitting element protruding from the first via layer, and a top surface of the light emitting element, a first insulating layer on the common electrode, a partition wall unit on the first insulating layer and overlapping the bank layer, a second insulating layer on the partition wall unit, and a reflective layer around a side of the partition wall unit.

### CROSS-REFERENCE TO RELATED APPLICATION

The present application claims priority to and the benefit of Korean Patent Application No. 10-2023-0112629, filed on Aug. 28, 2023, in the Korean Intellectual Property Office, the entire disclosure of which is incorporated by reference herein.

### BACKGROUND

### 1. Field

The present disclosure relates to a display device.

### 2. Description of the Related Art

Display devices are becoming increasingly important with the development of multimedia. In response to this, various types of display devices, such as organic light emitting diode (OLED) displays and liquid crystal displays (LCD), are being used.

### SUMMARY

A display device for displaying an image includes a display panel such as a light emitting display panel or a liquid crystal display panel. Among them, the light emitting display panel may include light emitting elements such as light emitting diodes (LEDs). For example, LEDs include organic light emitting diodes (OLEDs) that utilize organic materials as light emitting materials, inorganic light emitting diodes that utilize inorganic materials as light emitting materials, and the like.

Aspects and features of embodiments of the present disclosure provide a display device that may improve the light emission efficiency of a light emitting element.

However, aspects and features of embodiments of the present disclosure are not limited to the one set forth herein. The above and other aspects and features of embodiments of the present disclosure will become more apparent to one of ordinary skill in the art to which the present disclosure pertains by referencing the detailed description of the present disclosure given below.

According to one or more embodiments, a display device includes a pixel electrode on a substrate, a bank layer on the substrate and the pixel electrode and dividing a light emitting area and a light non-emitting area, a light emitting element on the pixel electrode and including a first semiconductor layer, a second semiconductor layer, and an active layer interposed between the first semiconductor layer and the second semiconductor layer, a first via layer on the pixel electrode and around at least a portion of a side of the light emitting element, a common electrode on the first via layer, a side of a light emitting element protruding from the first via layer, and a top surface of the light emitting element, a first insulating layer on the common electrode, a partition wall unit on the first insulating layer and overlapping the bank layer, a second insulating layer on the partition wall unit, a reflective layer around a side of the partition wall unit on the second insulating layer and a side of the light emitting element on the first insulating layer, and on the first insulating layer between the partition wall unit and the light emitting element, a second via layer between the partition wall units and having an opening exposing the first insulating layer on the light emitting element and a wavelength conversion layer on the second via layer.

The display device further includes a deterioration prevention layer located between the second via layer and the wavelength conversion layer and including a base resin and a scatterer.

The partition wall unit includes a first partition wall on the first insulating layer and having a first width and a second partition wall on the first partition wall and having a second width, wherein the first width is greater than the second width.

The reflective layer includes a first reflective layer around a side of the first partition wall, a second reflective layer around a side of the second partition wall, a third reflective layer around a portion of the side of the light emitting element, and a fourth reflective layer located between the first reflective layer and the third reflective layer and between the second via layer and the first insulating layer.

The third reflective layer is in contact with the first insulating layer and has a height equal to the height of the second via layer.

The third reflective layer is around at least a portion of a side surface of the second semiconductor layer of the light emitting element on the first insulating layer.

The first via layer covers the bank layer and a portion of the pixel electrode on which the light emitting element is not disposed, wherein the second via layer covers the fourth reflective layer between the partition walls units and is around the third reflective layer.

The light emitting element further includes an element insulating layer around the first semiconductor layer, the active layer, and the second semiconductor layer, and a connection electrode located between the first semiconductor layer and the pixel electrode.

The display device further includes an element reflective layer spaced from the common electrode and around at least a portion of a side surface of the light emitting element on the element insulating layer.

The display device further includes a capping layer, an overcoat layer, and a color filter layer sequentially arranged on the wavelength conversion layer and the partition wall unit.

The display device further includes a touch sensing unit located between the overcoat layer and the color filter layer.

According to one or more embodiments, a display device includes a first electrode and a second electrode on a substrate, a bank layer on the substrate, the first electrode, and the second electrode, and dividing a light emitting area and a light non-emitting area, a light emitting element including a first contact electrode, a second contact electrode, a first semiconductor layer on the first contact electrode, an active layer, and a second semiconductor layer on the second contact electrode and the active layer, a first via layer on the first electrode and the second electrode and around at least a portion of a side of the light emitting element, a first insulating layer on the first via layer, a side surface of the light emitting element protruding from the first via layer, and a top surface of the light emitting element, a partition wall unit on the first insulating layer and overlapping the bank layer, a second insulating layer on the partition wall unit, a reflective layer around a side of the partition wall unit on the second insulating layer and a side of the light emitting element on the first insulating layer, and on the first insulating layer between the partition wall unit and the light emitting element, a second via layer located between the partition wall units, and a wavelength conversion layer located on the second via layer.

The display device further includes a deterioration prevention layer located between the second via layer and the wavelength conversion layer and including a base resin and a scatterer.

The partition wall unit includes a first partition wall on the first insulating layer and having a first width and a second partition wall on the first partition wall and having a second width, wherein the first width is greater than the second width.

The reflective layer includes a first reflective layer around a side of the first partition wall, a second reflective layer around a side of the second partition wall, a third reflective layer around a portion of the side of the light emitting element, and a fourth reflective layer located between the first reflective layer and the third reflective layer and between the second via layer and the first insulating layer.

The third reflective layer is in contact with the first insulating layer and has a height equal to the height of the second via layer.

The third reflective layer is around at least a portion of a side surface of the second semiconductor layer of the light emitting element on the first insulating layer.

The first via layer covers the bank layer and a portion of the first electrode and the second electrode on which the light emitting element is not located, wherein the second via layer covers the fourth reflective layer between the partition walls units and surrounds the third reflective layer.

A height of the first partition wall is greater than or equal to a height of the second partition wall.

The display device further includes a capping layer, an overcoat layer, and a color filter layer sequentially arranged on the wavelength conversion layer and the partition wall unit.

A display device according to one or more embodiments of the present disclosure may improve the light emission efficiency of the light emitting element by surrounding the inner wall of the wavelength conversion layer with a reflective layer.

However, the effects, aspects, and features of embodiments of the present disclosure are not limited to the aforementioned effects, aspects, and features and various other effects, aspects, and features are included in the present disclosure.

### BRIEF DESCRIPTION OF THE DRAWINGS

FIG. 1 is a perspective view illustrating a display device according to one or more embodiments.

FIGS. 2 and 3 are plan views illustrating a display device according to one or more embodiments.

FIG. 4 is a circuit diagram illustrating a first sub-pixel of a display panel according to one or more embodiments.

FIG. 5 is a circuit diagram illustrating a first sub-pixel of a display panel according to one or more embodiments.

FIG. 6 is a cross-sectional view schematically illustrating a display device according to one or more embodiments.

FIG. 7 is an enlarged view schematically illustrating the first light emitting area described with reference to FIG. 6.

FIG. 8 is a cross-sectional view illustrating a pixel electrode and a light emitting element according to one or more embodiments described with reference to FIG. 6.

FIG. 9 is a plan view illustrating light emitting areas and areas of a reflective layer according to one or more embodiments.

FIG. 10 is a plan view illustrating light emitting areas and areas of a reflective layer according to one or more embodiments.

FIG. 11 is a cross-sectional view of a pixel electrode and a light emitting element according to one or more embodiments.

FIG. 12 is a cross-sectional view of a pixel electrode and a light emitting element according to one or more embodiments.

FIG. 13 is a cross-sectional view of a pixel electrode and a light emitting element according to one or more embodiments.

FIG. 14 is a cross-sectional view schematically illustrating a display device according to one or more embodiments.

FIG. 15 is an enlarged view schematically illustrating the first light emitting area described with reference to FIG. 14.

FIG. 16 is a cross-sectional view illustrating a pixel electrode and a light emitting element according to one or more embodiments described with reference to FIG. 14.

FIG. 17 is a cross-sectional view schematically illustrating a display device according to one or more embodiments.

FIG. 18 is an enlarged view schematically illustrating the first light emitting area described with reference to FIG. 17.

FIG. 19 is a cross-sectional view schematically illustrating a display device according to one or more embodiments.

FIG. 20 is an enlarged layout view illustrating in detail one example of the touch node described with reference to FIG. 19.

FIG. 21 is a cross-sectional view schematically illustrating a display device according to one or more embodiments.

FIG. 22 is an enlarged view schematically illustrating the first light emitting area described with reference to FIG. 21.

FIG. 23 is a cross-sectional view illustrating a pixel electrode and a light emitting element according to one or more embodiments described with reference to FIG. 22.

FIGS. 24-43 are diagrams for illustrating a method of manufacturing a display device according to one or more embodiments.

FIG. 44 is an example diagram schematically showing a virtual reality device including a display device according to one or more embodiments.

FIG. 45 is an example diagram schematically showing a smart device including a display device according to one or more embodiments.

FIG. 46 is a diagram of an example schematically showing a vehicle including a display device according to one or more embodiments.

FIG. 47 is a diagram of an example schematically showing a transparent display device including a display device according to one or more embodiments.

### DETAILED DESCRIPTION

One or more embodiments will now be described more fully hereinafter with reference to the accompanying drawings. One or more embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to the another element, or “electrically connected” or “electrically coupled” to the another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, one or more embodiments of the present disclosure will be described in detail with reference to the accompanying drawings.

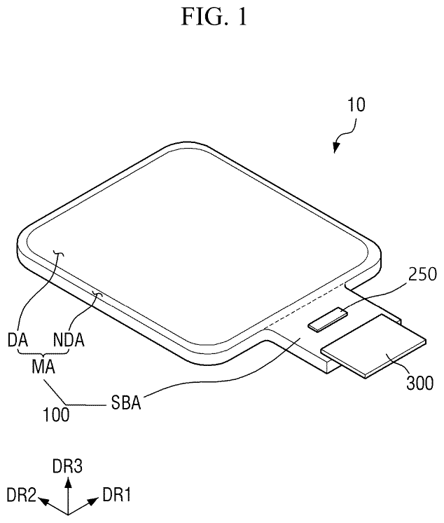

FIG. 1 is a perspective view illustrating a display device according to one or more embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books portable multimedia players (PMP), navigation, and ultra mobile PCs (UMPC), as well as display screens for a variety of products such as televisions, laptops, monitors, billboards, and/or the internet of things (IOT) devices.

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, the subminiature light-emitting diode is described herein as a micro light-emitting diode for convenience of explanation.

The display device 10 includes a display panel 100, a display driving circuit 250, and a circuit board 300.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 may include curved portions with a constant curvature or a changing curvature formed at left and right ends. Additionally, the display panel 100 may be formed to be flexible, such as to be able to be bent, curved, folded, and/or rolled.

The substrate of the display panel 100 may include a main area MA and a sub-area SBA.

The main area MA may include a display area DA that is configured to display an image and a non-display area NDA that is a peripheral area of the display area DA and disposed along one or more edges or a periphery of the display area DA. The display area DA may include a plurality of pixels that display an image. For example, the pixel may include a first sub-pixel that is configured to emit first light, a second sub-pixel that is configured to emit second light, and a third sub-pixel that is configured to emit third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not limited thereto. For example, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a rigid printed circuit board (PCB), or a flexible film such as a chip on film.

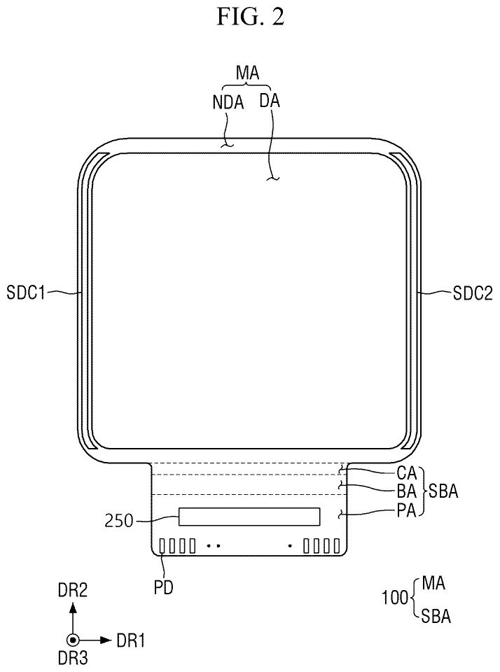

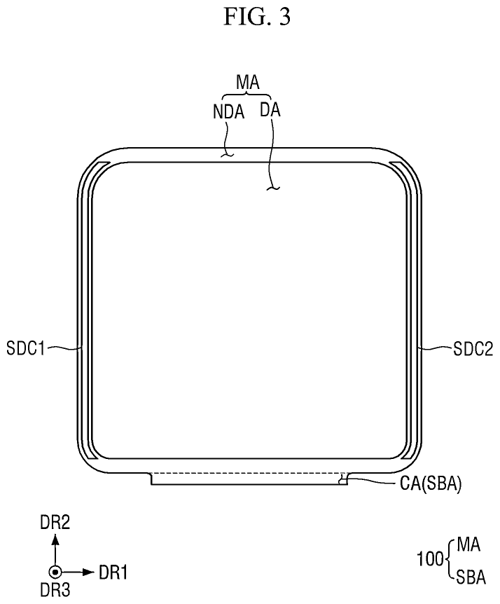

FIGS. 2 and 3 are plan views illustrating a display device according to one or more embodiments. FIG. 2 illustrates that the sub-area SBA is unfolded without being bent. FIG. 3 illustrates that the sub-area SBA is bent.

Referring to FIGS. 2 and 3, the display panel 100 may include the main area MA and the sub-area SBA.

The main area MA may include the display area DA that is configured to display an image and the non-display area NDA that is a peripheral area of the display area DA. The display area DA may occupy most of the main area MA. The display area DA may be placed in the center of the main area MA.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit SDC1 and a second scan driving unit SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, it is not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length of the sub-area SBA in the first direction DR1 is smaller than the length of the main area MA in the first direction DR1 or may be substantially equal to the length of the main area MA in the first direction DR1. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

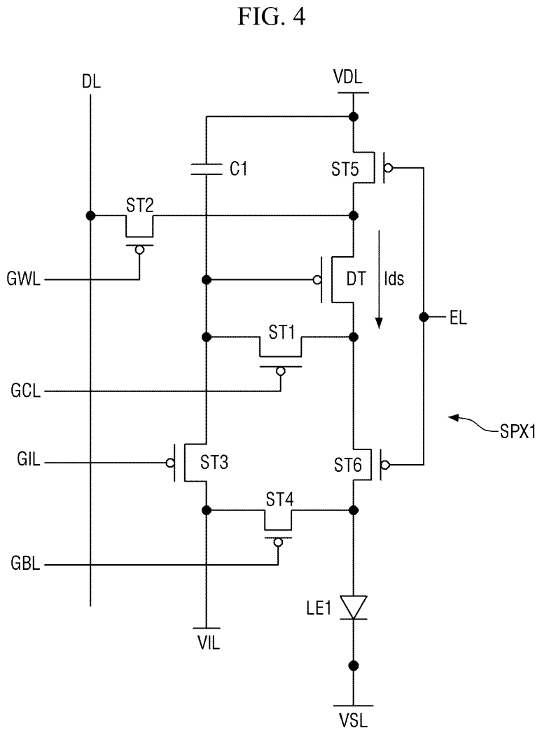

FIG. 4 is a circuit diagram illustrating a first sub-pixel of a display panel according to one or more embodiments.

Referring to FIG. 4, the first sub-pixel SPX1 according to one or more embodiments may be connected to scan lines GWL, GIL, GCL, and GBL, light emitting lines EL, and data lines DL. For example, the first sub-pixel SPX1 may be connected to a write scan line GWL, an initialization scan line GIL, the control scan line GCL, the bias scan line GBL, a light emitting line EL, and the data line DL.

The first sub-pixel SPX1 according to one or more embodiments includes a driving transistor DT, switch elements, a capacitor C1, and a first light emitting element LE1. The switch elements include first to sixth transistors ST1, ST2, ST3, ST4, ST5, and ST6.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode of the driving transistor DT.

The first light emitting element LE1 may be a micro light-emitting diode.

The first light emitting element LE1 is configured to emit light according to the driving current Ids. The amount of light emitted from the first light-emitting element LE1 may be proportional to the driving current Ids. An anode electrode of the first light emitting element LE1 may be connected to the first electrode of the fourth transistor ST4 and the second electrode of the sixth transistor ST6, a cathode electrode may be connected to the second power supply line VSL to which the second power supply voltage is applied.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on when a scan signal of the gate low voltage and an emission signal are applied to the control scan line GCL, the initialization scan line GIL, the write scan line GWL, the bias scan line GBL, and the light emitting line EL, respectively. One electrode of the third transistor ST3 and one electrode of the fourth transistor ST4 may be connected to an initialization voltage line VIL.

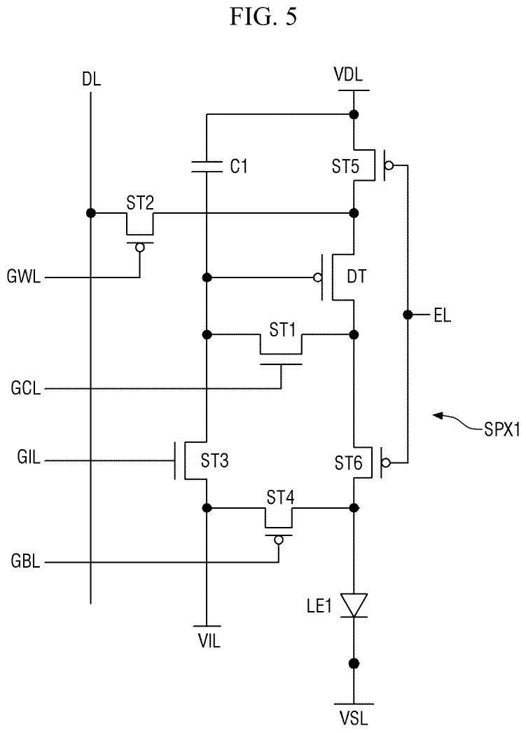

FIG. 5 is a circuit diagram illustrating a first sub-pixel of a display panel according to one or more embodiments.

Referring to FIG. 5, the driving transistor DT, the second transistor ST2, the fourth transistor ST4, the fifth transistor ST5, and the sixth transistor ST6 are formed of p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Because the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal with a gate high voltage is applied to the initialization scan line GIL. In comparison, the second transistor ST2, the fourth transistor ST4, the fifth transistor ST5, and the sixth transistor ST6 are formed as p-type MOSFET, so they may be turned on when a scan signal with a gate low voltage and an emission signal are applied to the write scan line GWL, the bias scan line GBL, and the light emitting line EL, respectively.

Alternatively, the fourth transistor ST4 in FIG. 4 may be formed of the n-type MOSFET. In this case, the active layer of fourth transistor ST4 may be formed of the oxide semiconductor. When the fourth transistor ST4 is formed of n-type MOSFET, it may be turned on when a bias scan signal of a gate high voltage is applied to the bias scan line GBL.

For example, the first transistor ST1 is connected between the second electrode and the gate electrode of the driving transistor DT. The second transistor ST2 is connected between the data line DL and the first electrode of the driving transistor DT. The third transistor ST3 is connected between the gate electrode of the driving transistor DT and the initialization voltage line VIL, the fourth transistor ST4 may be connected between the initialization voltage line VIL and the second electrode of the sixth transistor ST6, the fifth transistor ST5 is connected between the first power supply line VDL and the first electrode of the driving transistor DT, and the sixth transistor ST6 is connected between the second electrode of the driving transistor DT and the first light emitting element LE1. The gate electrodes of the fifth and sixth transistors ST5 and ST6 are connected to the light emitting line EL.

Alternatively, in one or more embodiments, the first to sixth transistors ST1, ST2, ST3, ST4, ST5, and ST6 and the driving transistor DT may all be formed as n-type MOSFET.

In one or more embodiments, the circuit diagram of the second sub-pixel and the third sub-pixel according to one or more embodiments are substantially the same as the circuit diagram of the first sub-pixel SPX1 described in conjunction with FIGS. 4 and 5, so a description thereof will be omitted.

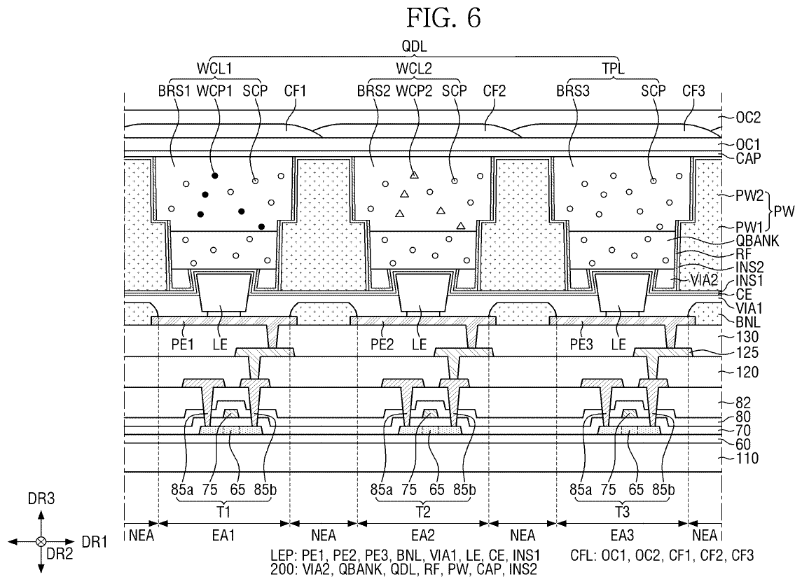

FIG. 6 is a cross-sectional view schematically illustrating a display device according to one or more embodiments.

Referring to FIG. 6, the display device 10 may include a substrate 110, a light emitting element unit LEP, a wavelength control unit 200, and a color filter layer CFL.

The substrate 110 may be an insulating substrate. The substrate 110 may include a transparent material. For example, the substrate 110 may include a transparent insulating material such as glass, quartz, etc. The substrate 110 may be a rigid substrate. However, the substrate 110 is not limited thereto and may include plastic such as polyimide and may have flexible characteristics that allow it to be curved, bent, folded, and/or rolled. A plurality of light emitting areas EA1, EA2, and EA3 and a light non-emitting area NEA may be defined in the substrate 110.

Switching elements T1, T2, and T3 may be located on the substrate 110. In one or more embodiments, the first switching element T1 may be located in the first light emitting area EA1 of the substrate 110, the second switching element T2 may be located in the second light emitting area EA2, and the third switching element T3 may be located in the third light emitting area EA3. However, it is not limited thereto, and in one or more embodiments, at least one of the first switching element T1, the second switching element T2, and the third switching element T3 may be located in the light non-emitting area NEA.

In one or more embodiments, the first switching element T1, the second switching element T2, and the third switching element T3 may each be a thin film transistor (TFT) including amorphous silicon, polysilicon, and/or an oxide semiconductor. In one or more embodiments, a plurality of signal lines (e.g., gate lines, data lines, power supply lines, etc.) that transmit signals to each switching element may be further positioned on the substrate 110.

Each switching element T1, T2, and T3 may include a semiconductor layer 65, a gate electrode 75, a source electrode 85a, and a drain electrode 85b.

Specifically, a buffer layer 60 may be disposed on the substrate 110. The buffer layer 60 may be disposed to cover the entire surface of the substrate 110. The buffer layer 60 includes silicon nitride, silicon oxide, and/or silicon oxynitride, and may be made of a single layer or a double layer thereof.

The semiconductor layer 65 may be disposed on the buffer layer 60. The semiconductor layer 65 may form a channel for each switching element T1, T2, and T3. The semiconductor layer 65 may include amorphous silicon, polycrystalline silicon, and/or an oxide semiconductor. For example, the oxide semiconductor may include a binary compound (ABₓ), a ternary compound (ABₓC_{y}), or a quaternary compound (ABₓC_{y}D_{z}) containing, for example, indium, zinc, gallium, tin, titanium, aluminum, hafnium (Hf), zirconium (Zr), magnesium (Mg), and/or the like. In one or more embodiments, the semiconductor layer 65 may include indium gallium zinc oxide (IGZO).

The gate insulating layer 70 may be disposed on the semiconductor layer 65 and the buffer layer 60. The gate insulating layer 70 may include a silicon compound, metal oxide, and/or the like. For example, the gate insulating layer 70 may include a silicon oxide, a silicon nitride, a silicon oxynitride, an aluminum oxide, a tantalum oxide, a hafnium oxide, a zirconium oxide, a titanium oxide, and/or the like. In one or more embodiments, the gate insulating layer 70 may include silicon oxide.

The gate electrode 75 may be disposed on the gate insulating layer 70. The gate electrode 75 may be disposed to overlap the semiconductor layer 65 in the third direction DR3. The gate electrode 75 may include a conductive material. The gate electrode 75 may include a metal oxide such as ITO, IZO, ITZO, In₂O₃, and/or a metal such as copper (Cu), titanium (Ti), aluminum (Al), molybdenum (Mo), tantalum (Ta), calcium (Ca), chromium (Cr), magnesium (Mg), and/or nickel (Ni). For example, the gate electrode 75 may be made of a Cu/Ti double layer in which an upper layer of copper is stacked on a lower layer of titanium but is not limited thereto.

A first interlayer insulating layer 80 and a second interlayer insulating layer 82 may be disposed on the gate electrode 75 and the gate insulating layer 70. The first interlayer insulating layer 80 may be directly disposed on the gate electrode 75, and the second interlayer insulating layer 82 may be directly disposed on the first interlayer insulating layer 80. The first interlayer insulating layer 80 and the second interlayer insulating layer 82 each include an inorganic insulating material such as silicon oxide, silicon nitride, silicon oxynitride, hafnium oxide, aluminum oxide, titanium oxide, tantalum oxide, zinc oxide, and/or the like. However, the present disclosure is not limited thereto, and the second interlayer insulating layer 82 may include an organic insulating material capable of flattening the lower-level difference. In this embodiment, two interlayer insulating layers, the first interlayer insulating layer 80 and the second interlayer insulating layer 82, are illustrated and described, but the present disclosure is not limited thereto, and only one interlayer insulating layer may be disposed.

The source electrode 85a and the drain electrode 85b may be disposed on the second interlayer insulating layer 82. The source electrode 85a and the drain electrode 85b may contact the semiconductor layer 65 through contact holes penetrating the first interlayer insulation layer 80, the second interlayer insulation layer 82, and the gate insulation layer 70, respectively. The source electrode 85a and the drain electrode 85b may include metal oxides such as ITO, IZO, ITZO, In₂O₃, and/or metals such as copper (Cu), titanium (Ti), aluminum (Al), molybdenum (Mo), tantalum (Ta), calcium (Ca), chromium (Cr), magnesium (Mg), and/or nickel (Ni). For example, the source electrode 85a and the drain electrode 85b may be made of a Cu/Ti double layer in which an upper layer of copper is stacked on a lower layer of titanium but is not limited thereto.

A first planarization layer 120 may be disposed on the first switching element T1, the second switching element T2, and the third switching element T3 on the second interlayer insulating layer 82. The first planarization layer 120 may include an organic material. For example, the first planarization layer 120 may include acrylic resin, epoxy resin, imide resin, ester resin, etc. In one or more embodiments, the first planarization layer 120 may include a positive photosensitive material or a negative photosensitive material.

A pixel connection electrode 125 may be disposed on the first planarization layer 120. The pixel connection electrode 125 is disposed to correspond to each of the first switching element T1, the second switching element T2, and the third switching element T3, and may be electrically connected to them. The pixel connection electrode 125 may connect the pixel electrodes PE1, PE2, and PE3 described later to the switching elements T1, T2, and T3 described above. The pixel connection electrode 125 may contact the switching elements T1, T2, and T3 through a contact hole penetrating the first planarization layer 120.

A second planarization layer 130 may be disposed on the first planarization layer 120 and the pixel connection electrode 125. The second planarization layer 130 flattens the lower-level difference and may include the same material as the first planarization layer 120 described above.

The light emitting element unit LEP may be disposed on the second planarization layer 130. The light emitting element unit LEP may include a plurality of pixel electrodes PE1, PE2, and PE3, a plurality of light emitting elements LE, and a common electrode CE. Additionally, the light emitting element unit LEP may further include a bank BNL and a first via layer VIA1 that compartmentalize each light emitting area EA1, EA2, and EA3.

The plurality of pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as the first electrode of the light emitting element LE and may be an anode electrode or a cathode electrode. The first pixel electrode PE1 may be located in the first light emitting area EA1, the second pixel electrode PE2 may be located in the second light emitting area EA2, and the third pixel electrode PE3 may be located in the third light emitting area EA3. The light emitting elements LE may be arranged regularly with certain rules (e.g., predetermined rules). For example, the light emitting elements LE may be arranged to be spaced from each other at regular intervals.

Each light emitting element LE may be generally disposed on each pixel electrode PE1, PE2, and PE3. However, the present disclosure is not limited to this, and some light emitting elements LE may be disposed between each pixel electrode PE1, PE2, and PE3, may be partially disposed over one pixel electrode, or may not be disposed on any pixel electrode.

In one or more embodiments, the first pixel electrode PE1 may overlap with the first light emitting area EA1, the second pixel electrode PE2 may overlap with the second light emitting area EA2, and the third pixel electrode PE3 may overlap with the third light emitting area EA3.

Each pixel electrode PE1, PE2, and PE3 may be directly connected to the pixel connection electrode 125 through a contact hole penetrating the second planarization layer 130 and may be electrically connected to the respective switching elements T1, T2, and T3 through the pixel connection electrode 125. The first pixel electrode PE1, the second pixel electrode PE2, and the third pixel electrode PE3 may include metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), and/or a mixture thereof. Additionally, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have a two-layer structure in which a copper layer is stacked on a titanium layer, but the structure is not limited thereto.

The plurality of light emitting elements LE may be disposed on the first pixel electrode PE1, the second pixel electrode PE2, and the third pixel electrode PE3.

As shown in FIGS. 6 to 8, the light emitting elements LE may be disposed in each of the first light emitting area EA1, the second light emitting area EA2, and the third light emitting area EA3. The light emitting element LE may be a vertical light emitting diode element extending in the third direction DR3. That is, the length of the light emitting element LE in the third direction DR3 may be longer than the length in the horizontal direction. The length in the horizontal direction refers to the length in the first direction DR1 or the length in the second direction DR2. For example, the length of the light emitting element LE in the first direction DR1 or the length in the second direction DR2 may be approximately 1 μm to 5 μm but is not limited thereto. Additionally, the length of the light emitting element LE in the third direction DR3 may be approximately 7 μm to 10 μm. However, the present disclosure is not limited thereto, and the length of the light emitting element LE in the third direction DR3 may be equal to or smaller than the length in the horizontal direction.

The light emitting element LE may be a micro light emitting diode element.

The bank BNL may be formed to compartmentalize the pixel electrodes PE1, PE2, and PE3 on the second planarization layer 130 to define the light emitting area. The bank BNL may be arranged to cover the edges of the pixel electrodes PE1, PE2, and PE3. The bank BNL may be formed of an organic film such as acryl resin, epoxy resin, phenolic resin, polyamide resin, and/or polyimide resin.

The first via layer VIA1 may be disposed on the bank BNL and the pixel electrodes PE1, PE2, and PE3. The first via layer VIA1 covers the bank BNL and the pixel electrodes PE1, PE2, and PE3, and may flatten a step at the bottom to allow the common electrode CE to be formed as described later.

The common electrode CE may be disposed on the first via layer VIA1 and the plurality of light emitting elements LE. Specifically, the common electrode CE is disposed on one surface of the substrate 110 on which the light emitting element LE is formed and may be disposed entirely in the display area DA of the substrate 110. The common electrode CE is disposed to overlap each of the light emitting areas EA1, EA2, and EA3 and the light non-emitting area NEA, and may have a thickness small enough to allow light to be emitted.

Because the common electrode CE is disposed entirely on the substrate 110 and applies a common voltage, it may include a material with low resistance. Additionally, the common electrode CE may be formed to be thin to facilitate light transmission. For example, the common electrode CE may include a metal material with low resistance such as aluminum (Al), silver (Ag), copper (Cu), and/or the like, or a metal oxide such as ITO, IZO, ITZO, and/or the like. The thickness of the common electrode CE may be approximately 10 Å to 200 Å but is not limited thereto.

The above-described light emitting elements LE may receive a pixel voltage or anode voltage from each pixel electrode PE1, PE2, and PE3, and may receive a common voltage through the common electrode CE. The light emitting elements LE may emit light with a suitable luminance (e.g., a predetermined luminance) depending on a voltage difference between the pixel voltage and the common voltage. In one or more embodiments, by disposing a plurality of light emitting elements LE, that is, inorganic light emitting diodes, on the pixel electrodes PE1, PE2, and PE3, the situations where organic light emitting diodes are vulnerable to external moisture or oxygen are eliminated and the lifespan and reliability may be improved.

The light emitting element unit LEP may further include a first insulating layer INS1 covering the common electrode CE. The first insulating layer INS1 may be directly disposed on the common electrode CE. The first insulating layer INS1 covers the components disposed therebelow, for example, the light emitting elements LE and the common electrode CE and serves to protect them from moisture or debris. Therefore, the first insulating layer INS1 may also be referred to as a protective layer. The first insulating layer INS1 may include an inorganic material, for example, at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

The wavelength control unit 200 may be disposed on the light emitting element unit LEP. The wavelength control unit 200 may include a second via layer VIA2, a deterioration prevention layer QBANK, a wavelength conversion layer QDL, a second insulating layer INS2, a reflective layer RF, and a partition wall unit PW.

The partition wall unit PW is disposed on the first insulating layer INS1 and may compartmentalize the plurality of light emitting areas EA1, EA2, and EA3. The partition wall unit PW is arranged to extend in the first direction DR1 and the second direction DR2 and may be formed in a grid-like pattern throughout the display area DA. Additionally, the partition wall unit PW may not overlap with the plurality of light emitting areas EA1, EA2, and EA3 and may overlap with the light non-emitting area NEA.

The partition wall unit PW may serve to provide a space for the wavelength conversion layer QDL to be formed. To this end, the partition wall unit PW may include a first partition wall PW1 and a second partition wall PW2 disposed on the first partition wall PW1.

The partition wall unit PW may be composed of a two-layer structure of the first partition wall PW1 and the second partition wall PW2 and may be relatively thick to provide a space in which the wavelength conversion layer QDL is formed. For example, a width WH1 of the first partition wall PW1 is wider than the width WH2 of the second partition wall PW2. The width WH1 of the first partition wall PW1 may be approximately twice that of the second partition wall PW2. For example, the width WH1 of the first partition wall PW1 may be in the range of 5 μm to 10 μm, and the width WH2 of the second partition wall PW2 may be in the range of 3 μm to 5 μm. In one or more embodiments, the width WH1 of the first partition wall PW1 may be 8 μm, and the width WH2 of the second partition wall PW2 may be 4 μm. A height HP1 of the first partition wall PW1 may be greater than or equal to a height HP2 of the second partition wall PW2. For example, the height HP1 of the first partition wall PW1 may be in the range of 8 μm to 12 μm, and the height HP2 of the second partition wall PW2 may be in the range of 4 μm to 8 μm. In one or more embodiments, the height HP1 of the first partition wall PW1 may be 10 μm, and the height HP2 of the second partition wall PW2 may be 6 μm. The first partition wall PW1 and the second partition wall PW2 may include an organic insulating material so as to be thick. The organic insulating material may include, for example, epoxy-based resin, acrylic-based resin, cardo-based resin, and/or imide-based resin.

The second insulating layer INS2 may be disposed on the partition wall unit PW. The second insulating layer INS2 may be disposed along the side and top surfaces of the partition wall unit PW. The second insulating layer INS2 may be disposed to not overlap the light emitting areas EA1, EA2, and EA3 and to overlap the light non-emitting area NEA. The second insulating layer INS2 may entirely overlap the partition wall unit PW.

The reflective layer RF may be disposed on the first insulating layer INS1 and the second insulating layer INS2. The reflective layer RF is disposed on the side of the partition wall unit PW on the second insulating layer INS2, and may be disposed overlapping the light emitting areas EA1, EA2, and EA3 on the first insulating layer INS1 where no light emitting elements LE are disposed.

The reflective layer RF may reflect light emitted from the light emitting elements LE upward (e.g., to the third direction DR3). The reflective layer RF may include a metal material with high light reflectance. For example, the reflective layer RF may include aluminum and/or silver, and/or may be an alloy thereof.

The second via layer VIA2, the deterioration prevention layer QBANK, and the wavelength conversion layer QDL may be sequentially disposed in each light emitting area EA1, EA2, and EA3.

The second via layer VIA2 may be disposed in each light emitting area EA1, EA2, and EA3 compartmentalized by the partition wall unit PW. The second via layers VIA2 disposed in each light emitting area EA1, EA2, and EA3 may be spaced from each other. That is, the second via layers VIA2 may be formed in an island pattern spaced from each other. The second via layer VIA2 may be disposed to overlap the first light emitting area EA1, the second light emitting area EA2, and the third light emitting area EA3, respectively.

The deterioration prevention layer QBANK may be disposed on the second via layer VIA2. The deterioration prevention layer QBANK is disposed between the second via layer VIA2 and the wavelength conversion layer QDL to prevent heat generated from the light emitting element LE from being directly transferred to the wavelength conversion layer QDL. The deterioration prevention layer QBANK may prevent deterioration of the wavelength conversion layer QDL due to heat generated from the light emitting element LE.

The deterioration prevention layer QBANK may include a base resin BRS0 and a scatterer SCP dispersed in the base resin BRS0. The base resin BRS0 may include a light-transmitting organic material. For example, the base resin BRS0 may include epoxy resin, acrylic resin, cardo resin, and/or imide resin.

The scatterer SCP may scatter the light of the light emitting element LE in a random direction. The scatterer SCP may have a different refractive index from the base resin BRS0 and form an optical interface with the base resin BRS0. For example, the scatterer SCP may be a light scattering particle. The scatterer SCP is not particularly limited to any material capable of scattering at least a portion of the transmitted light, but may be, for example, metal oxide particles or organic particles. Examples of the metal oxide particles include titanium oxide (TiO₂), zirconium oxide (ZrO₂), aluminum oxide (Al₂O₃), indium oxide (In₂O₃), zinc oxide (ZnO), and/or tin oxide (SnO₂), and examples of organic particle include acrylic resins or urethane resins. The scatterer SCP may scatter light in a random direction regardless of the incident direction of the incident light without substantially converting the wavelength of the light.

The wavelength conversion layer QDL may be disposed on the deterioration prevention layer QBANK. The wavelength conversion layer QDL may convert or shift the peak wavelength of incident light into another specific peak wavelength and emit light of the another specific peak wavelength. The wavelength conversion layer QDL may convert the blue first light emitted from the light emitting element LE into red second light, green third light, or transmit the blue first light as is.

The wavelength conversion layer QDL may be disposed in each light emitting area EA1, EA2, and EA3 compartmentalized by the partition wall unit PW and may be disposed to be spaced from each other. That is, the wavelength conversion layer QDL may be formed in the island pattern spaced from each other.

The wavelength conversion layer QDL may be disposed to overlap the first light emitting area EA1, the second light emitting area EA2, and the third light emitting area EA3, respectively. In one or more embodiments, the wavelength conversion layer QDL may completely overlap the first light emitting area EA1, the second light emitting area EA2, and the third light emitting area EA3, respectively.

The wavelength conversion layer QDL may include a first wavelength conversion pattern WCL1 overlapping with the first light emitting area EA1, a second wavelength conversion pattern WCL2 overlapping with the second light emitting area EA2, and a light transmission pattern TPL overlapping the third light emitting area EA3.

The first wavelength conversion pattern WCL1 may be disposed to overlap the first light emitting area EA1. The first wavelength conversion pattern WCL1 may convert or shift the peak wavelength of incident light into another specific peak wavelength and emit light of the another specific peak wavelength. In one or more embodiments, the first wavelength conversion pattern WCL1 may convert and emit blue first light emitted from the light emitting element LE of the first light emitting area EA1 into second light, which is red light having a single peak wavelength in the range of about 610 nm to about 650 nm.

The first wavelength conversion pattern WCL1 may include a first base resin BRS1, a first wavelength conversion particle WCP1, and the scatterer SCP. The first base resin BRS1 may be the same material as the base resin BRS0 of the deterioration prevention layer QBANK but is not limited thereto. The first base resin BRS1 may include a light-transmitting organic material. For example, the first base resin BRS1 may include epoxy-based resin, acrylic-based resin, cardo-based resin, or imide-based resin.

The first wavelength conversion particle WCP1 may convert the first light incident from the light emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, and/or a phosphorescent material. For example, quantum dots may be particulate materials that emit light of a specific color as electrons transition from the conduction band to the valence band.

The quantum dots may be semiconductor nanocrystalline materials. Depending on its composition and size, the quantum dot may have a specific bandgap to absorb light and emit light with a unique wavelength. Examples of the semiconductor nanocrystals of the quantum dots include Group IV nanocrystals, Group II-VI compound nanocrystals, Group III-V compound nanocrystals, Group IV-VI compound nanocrystals, or combinations thereof.

The Group II-VI compound is a binary compound selected from the group consisting of CdSe, CdTe, ZnS, ZnSe, ZnTe, ZnO, HgS, HgSe, HgTe, MgSe, MgS, and mixtures thereof; ternary compounds selected from the group consisting of InZnP, AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-V compound is a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The Group IV-VI compounds may be selected from the group consisting of binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The Group IV element may be selected from the group consisting of Si, Ge, and mixtures thereof. The Group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In one or more embodiments, the quantum dot may have a core-shell structure including a core including a nanocrystal as described above and a shell surrounding the core. The shell of the quantum dot may act as a protective layer to prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, and/or combinations thereof.

For example, the oxides of said metals or non-metals may have examples of binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or ternary compounds such as MgAl₂O₄, CoFe₂O₄, NiFe₂O₄, CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but are not limited thereto.

The second wavelength conversion pattern WCL2 may be disposed to overlap the second light emitting area EA2. The second wavelength conversion pattern WCL2 may emit light of the another specific peak wavelength by converting or shifting the peak wavelength of incident light into another specific peak wavelength. In one or more embodiments, the second wavelength conversion pattern WCL2 converts the blue first light emitted from the light emitting element LE of the second light emitting area EA2 into green third light having a peak wavelength in the range of about 510 nm to 550 nm and emit the light.

The second wavelength conversion pattern WCL2 may include a second base resin BRS2 and a second wavelength conversion particle WCP2 and the scatterer SCP dispersed in the second base resin BRS2.

The second base resin BRS2 may be made of a material with high light transmittance, may be made of the same material as the first base resin BRS1, or may include at least one of the materials exemplified as their constituent materials.

The second wavelength conversion particle WCP2 may convert or shift the peak wavelength of incident light to another specific peak wavelength. In one or more embodiments, the second wavelength conversion particle WCP2 may convert the blue first light provided from the light emitting element LE into green third light having a peak wavelength in the range of about 510 nm to 550 nm and emit the light. Examples of the second wavelength conversion particle WCP2 include quantum dots, quantum rods, and/or phosphors. A more specific description of the second wavelength conversion particle WCP2 is substantially the same as or similar to that described above in the description of the first wavelength conversion particle WCP1 and will be omitted.

The light transmission pattern TPL may be arranged to overlap the third light emitting area EA3. The light transmission pattern TPL may transmit incident light. The light transmission pattern TPL may directly transmit the blue first light emitted from the light emitting element LE disposed in the third light emitting area EA3. The light transmission pattern TPL may include a third base resin BRS3 and the scatterer SCP dispersed in the third base resin BRS3. Because the third base resin BRS3 is substantially the same as or similar to the above-described first base resin BRS1, description thereof will be omitted.

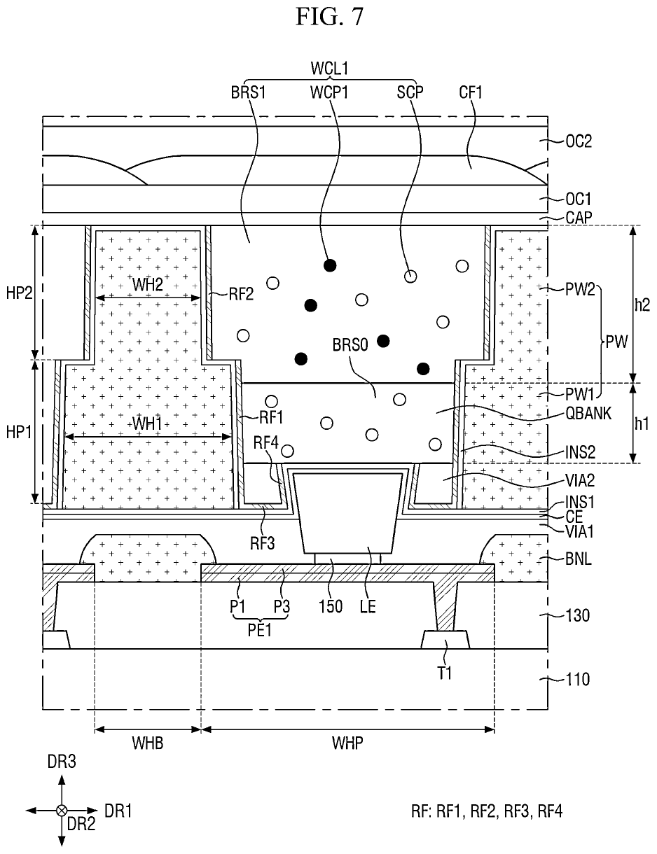

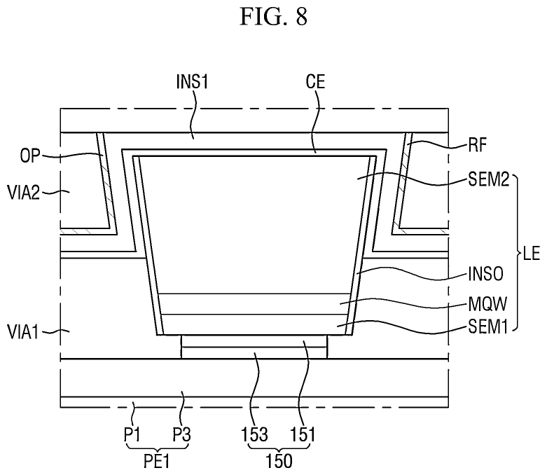

The light emitting element unit LEP and the wavelength control unit 200 will be described in detail with reference to FIGS. 7 and 8.

The first light, second light, and third light emitted from the above-described wavelength control unit 200 may respectively pass through a color filter layer CFL, which will be described later, to realize full color.

The wavelength control unit 200 may further include a capping layer CAP disposed on the partition wall unit PW and the wavelength conversion layer QDL. The capping layer CAP serves to cover the wavelength conversion layer QDL disposed below and protect it from moisture or debris. The capping layer CAP may include an inorganic material. For example, the capping layer CAP may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In one or more embodiments, the drawing illustrates that the capping layer CAP is formed as single layer, but the present disclosure is not limited thereto. For example, the capping layer CAP may be formed of multiple layers in which inorganic layers containing at least one of the materials that may be included in the capping layer CAP are alternately stacked. The thickness of the capping layer CAP may range from 0.05 μm to 2 μm but is not limited thereto.

In one or more embodiments, the color filter layer CFL may be disposed on the wavelength control unit 200. The color filter layer CFL may include a first overcoat layer OC1, a first color filter CF1, a second color filter CF2, a third color filter CF3, and a second overcoat layer OC2.

The first overcoat layer OC1 may be disposed on the wavelength control unit 200. The first overcoat layer OC1 may be directly disposed on the capping layer CAP of the wavelength control unit 200. The first overcoat layer OC1 may be disposed entirely over the display area DA and may have a flat surface. The first overcoat layer OC1 may flatten the step formed by the lower wavelength control unit 200 to facilitate the formation of the color filter layer CFL.

The first overcoat layer OC1 may include a light-transmitting organic material. For example, the first overcoat layer OC1 may include epoxy resin, acrylic resin, cardo resin, and/or imide resin. In one or more embodiments, the first overcoat layer OC1 is illustrated as a single layer, but it is not limited thereto and may be arranged to be stacked in multiple layers.

The first color filter CF1, the second color filter CF2, and the third color filter CF3 may be disposed on the first overcoat layer OC1. The first color filter CF1 may be disposed in the first light emitting area EA1, the second color filter CF2 may be disposed in the second light emitting area EA2, and the third color filter CF3 may be disposed in the third light emitting area EA3.

The first color filter CF1, the second color filter CF2, and the third color filter CF3 may include a colorant such as the dye or pigment that absorbs wavelengths other than the corresponding color wavelength. The first color filter CF1 may selectively transmit the second light (e.g., red light) and block or absorb the first light (e.g., blue light) and the third light (e.g., green light). The second color filter CF2 may selectively transmit the third light (e.g., green light) and block or absorb the first light (e.g., blue light) and the second light (e.g., red light). The third color filter CF3 may selectively transmit the first light (e.g., blue light) and block or absorb the second light (e.g., red light) and the third light (e.g., green light). For example, the first color filter CF1 may be a red color filter, the second color filter CF2 may be a green color filter, and the third color filter CF3 may be a blue color filter.

In one or more embodiments, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted to the top of the substrate 110 to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may prevent color distortion due to reflection of external light.

The plane area of each of the first color filter CF1, the second color filter CF2, and the third color filter CF3 may be larger than the planar area of each of the plurality of light emitting areas EA1, EA2, and EA3. For example, the plane area of the first color filter CF1 may be larger than the planar area of the first light emitting area EA1. The plane area of the second color filter CF2 may be larger than the planar area of the second light emitting area EA2. The plane area of the third color filter CF3 may be larger than the planar area of the third light emitting area EA3. However, it is not limited thereto, and the planar area of each of the first color filter CF1, the second color filter CF2, and the third color filter CF3 may be equal to the planar area of each of the plurality of light emitting areas EA1, EA2, and EA3.

The second overcoat layer OC2 may be disposed on the first color filter CF1, the second color filter CF2, and the third color filter CF3. The second overcoat layer OC2 may be directly disposed on the first color filter CF1, the second color filter CF2, and the third color filter CF3. The second overcoat layer OC2 may be disposed entirely in the display area DA and may have a flat surface. The second overcoat layer OC2 may flatten the step formed by the lower first color filter CF1, the second color filter CF2, and the third color filter CF3. The second overcoat layer OC2 may include a light-transmitting organic material and may be substantially the same as or similar to the first overcoat layer OC1 described above.

As described above, the display device 10 according to one or more embodiments may improve the light emission efficiency of the light emitting element LE by forming the reflective layer RF on the side of the partition wall unit PW and on the substrate 110 in a region not overlapping with the light emitting element LE between the partition wall and the adjacent partition wall.

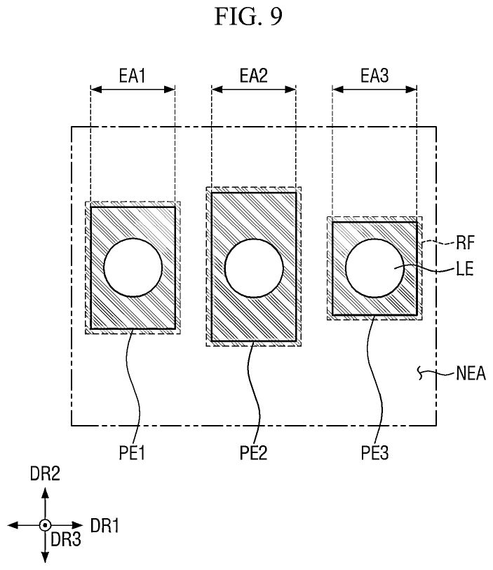

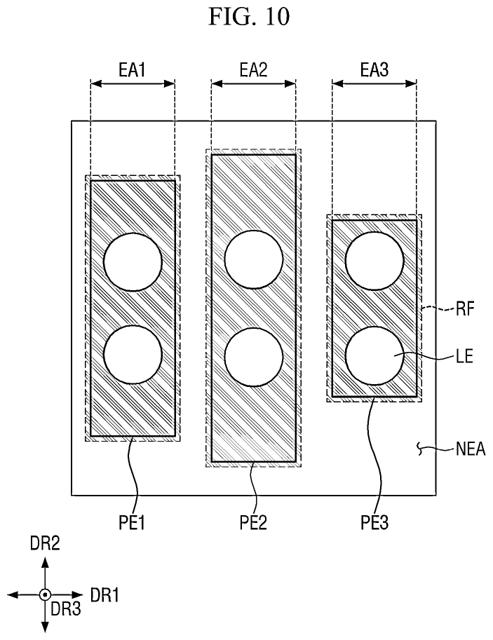

FIG. 7 is an enlarged view schematically illustrating the first light emitting area described with reference to FIG. 6. FIG. 8 is a cross-sectional view illustrating a pixel electrode and a light emitting element according to one or more embodiments described with reference to FIG. 6. FIG. 9 is a plan view illustrating light emitting areas and areas of a reflective layer according to one or more embodiments. FIG. 10 is a plan view illustrating light emitting areas and areas of a reflective layer according to one or more embodiments.

Referring to FIGS. 7 and 8, in this embodiment, each pixel electrode PE1, PE2, and PE3 may include a lower electrode layer P1 and an upper electrode layer P3. In the following, the first pixel electrode PE1 will be described as an example.

The lower electrode layer P1 may be disposed at the bottom of the first pixel electrode PE1 and may be electrically connected to the switching element. The lower electrode layer P1 may serve to provide the first pixel electrode PE1 with adhesion to the second planarization layer 130. The lower electrode layer P1 may include a metal, for example, titanium.

The upper electrode layer P3 is disposed on the lower electrode layer P1 and may be in direct contact with the light emitting element LE. The upper electrode layer P3 may be disposed between the lower electrode layer P1, and the light emitting element LE and may serve to provide the first pixel electrode PE1 with adhesion to the light emitting element LE. The upper electrode layer P3 may include a metal, for example, copper.

The light emitting element LE may include a connection electrode 150, a first semiconductor layer SEM1, an active layer MQW, and a second semiconductor layer SEM2 arranged along the thickness direction of the substrate 110, that is, the third direction DR3. The connection electrode 150, the first semiconductor layer SEM1, the active layer MQW, and the second semiconductor layer SEM2 may be sequentially stacked along the third direction DR3. The light emitting element LE may include an element insulating layer INS0 surrounding the first semiconductor layer SEM1, the active layer MQW, and the second semiconductor layer SEM2.

The light emitting element LE may have a cylindrical shape, a disk shape, or a rod shape where the height is longer than the width. However, the light emitting element LE is not limited thereto, and may have a shape such as a rod, a wire, a tube, a polygonal column shape such as a regular hexahedron, a rectangular parallelepiped, a hexagonal column, or a shape extending in one direction but having a partially inclined outer surface.

The connection electrode 150 may be disposed on top of each of the plurality of pixel electrodes PE1, PE2, and PE3. In the following, the light emitting element LE disposed on the first pixel electrode PE1 will be described as an example, but is not limited thereto, and the structure of the light emitting element LE disposed on the second pixel electrode PE2 and the third pixel electrode PE3 may be configured in the same manner.

The connection electrode 150 may include a reflective layer 151 and a connection layer 153. The reflective layer 151 may serve to reflect light emitted from the active layer MQW of the light emitting element LE. The reflective layer 151 may be disposed adjacent to the active layer MQW of the light emitting element LE. The reflective layer 151 may include a metal material that is conductive and has a high light reflectance. The reflective layer 151 may include, for example, aluminum (Al) and/or silver (Ag), or may be an alloy thereof.

The connection layer 153 may serve to transmit a light emitting signal from the first pixel electrode PE1 to the light emitting element LE. The connection layer 153 may be an ohmic connection electrode. However, it may be a Schottky connection electrode. The connection layer 153 may be disposed at the bottom of the light emitting element LE and may be disposed farther from the active layer MQW compared to the reflective layer 151. The connection layer 153 may include at least one of gold (Au), copper (Cu), tin (Sn), silver (Ag), aluminum (Al), and titanium (Ti). For example, the connection layer 153 may include a 9:1 alloy, 8:2 alloy, or 7:3 alloy of gold and tin, or may include an alloy of copper, silver, and tin (e.g., SAC305).

In FIG. 8, the light emitting element LE is illustrated to include the connection electrode 150 having a double-layer structure of the reflective layer 151 and the connection layer 153, but the present disclosure is not limited thereto. In some cases, the light emitting element LE may include the connection electrode 150 with a greater number of layers stacked, or some layers may be omitted.

The first semiconductor layer SEM1 may be disposed on the connection electrode 150. The first semiconductor layer SEM1 may be disposed adjacent to the first pixel electrode PE1. The first semiconductor layer SEM1 may be a p-type semiconductor and may include a semiconductor material having a chemical formula of AlₓGa_{y}In_{1-x-y}N (0≤x≤1, 0≤y≤1, 0≤x+y≤1). For example, it may be one or more of p-type doped AlGaInN, GaN, AlGaN, InGaN, AlN, and InN. The first semiconductor layer SEM1 may be doped with a p-type dopant, and the p-type dopant may be Mg, Zn, Ca, Sr, Ba, and/or the like. For example, the first semiconductor layer SEM1 may be p-GaN doped with p-type Mg. The thickness of the first semiconductor layer SEM1 may range from 30 nm to 200 nm but is not limited thereto.

The active layer MQW may be disposed on the first semiconductor layer SEM1. The active layer MQW may emit light by recombining electron-hole pairs according to electrical signals applied through the first semiconductor layer SEM1 and the second semiconductor layer SEM2. The active layer MQW may emit first light having a central wavelength range of 450 nm to 495 nm, that is, light in a blue wavelength band.

The active layer MQW may include a single or multiple quantum well structure. If the active layer MQW includes a material with a multi-quantum well structure, it may be a stacked structure with a plurality of well layers and a barrier layer alternating with each other. In this case, the well layer may be formed of InGaN and the barrier layer may be formed of GaN or AlGaN, but is not limited thereto. The thickness of the well layer may be approximately 1 to 4 nm, and the thickness of the barrier layer may be 3 nm to 10 nm.

Alternatively, the active layer MQW may have a structure in which a semiconductor material having a large energy band gap and a semiconductor material having a small energy band gap are alternately stacked with each other and may include other Group Ill to Group V semiconductor materials depending on the wavelength band of the emitted light. The light emitted from the active layer MQW is not limited to the first light and may emit second light (e.g., light of a green wavelength band) or third light (e.g., light of a red wavelength band) according to circumstances. In one or more embodiments, when indium is included among the semiconductor materials included in the active layer MQW, the color of emitted light may vary according to the amount of indium. For example, when the indium content is about 15%, the light in a blue wavelength band may be emitted, when the indium content is about 25%, the light in a green wavelength band may be emitted, and when the indium content is about 35% or more, the light in a red wavelength band may be emitted.

The second semiconductor layer SEM2 may be disposed on the active layer MQW. The second semiconductor layer SEM2 may be an n-type semiconductor. The second semiconductor layer SEM2 may include a semiconductor material having the formula AlₓGa_{y}In_{1-x-y}N (0≤x≤1, 0≤y≤1, 0≤x+y≤1). For example, it may be one or more of n-type doped AlGaInN, GaN, AlGaN, InGaN, AlN, and InN. The second semiconductor layer SEM2 may be doped with an n-type dopant, and the n-type dopant may be Se, Si, Ge, Sn, and/or the like. For example, the second semiconductor layer SEM2 may be n-GaN doped with n-type Si. The thickness of the second semiconductor layer SEM2 may range from 2 μm to 4 μm but is not limited thereto.

In one or more embodiments, an electron blocking layer may be further included between the first semiconductor layer SEM1 and the active layer MQW. The electron blocking layer may be a layer to suppress or prevent too many electrons from flowing into the active layer MQW. For example, the electron blocking layer may be p-AlGaN doped with p-type Mg. The thickness of the electron blocking layer may range from 10 nm to 50 nm but is not limited thereto. Additionally, the electron blocking layer may be omitted.

Additionally, a superlattice layer may be further included between the active layer MQW and the second semiconductor layer SEM2. The superlattice layer may be a layer for relieving stress between the second semiconductor layer SEM2 and the active layer MQW. For example, the superlattice layer may be formed of InGaN or GaN. The thickness of the superlattice layer may be approximately 50 to 200 nm. The superlattice layer may be omitted.

The element insulating layer INS0 may be around (e.g., may surround) the sides of the light emitting element LE, for example, the outer surface (e.g., the outer peripheral or circumferential surface). The element insulation layer INS0 may insulate the light emitting elements LE from other layers. The element insulation layer INS0 may be directly disposed on the outer surface (e.g., the outer peripheral or circumferential surface) of the first semiconductor layer SEM1, the active layer MQW, and the second semiconductor layer SEM2 and surround them. In one or more embodiments, the element insulation layer INS0 may surround the entire outer surface (e.g., the outer peripheral or circumferential surface) of the first semiconductor layer SEM1, the active layer MQW, and the second semiconductor layer SEM2.

As shown in FIG. 8, the element insulation layer INS0 may be arranged to surround the light emitting elements LE. The element insulation layer INS0 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), and/or the like. The thickness of the element insulation layer INS0 may be approximately 0.1 μm but is not limited thereto.

The first via layer VIA1 may be disposed on the first pixel electrode PE1 and the bank BNL. The width WHP of the first pixel electrode PE1 may be two to three times the width WHB of the bank BNL but is not limited thereto. For example, the width WHP of the first pixel electrode PE1 may be 19 μm, and the width WHB of the bank BNL may be 7 μm.

The first via layer VIA1 extends from the top surface of each pixel electrode PE1, PE2, and PE3 and the bank BNL in the third direction DR3 to surround the light emitting elements LE but the top surface of the first via layer VIA1 may be disposed lower than the height of the light emitting element LE.

The first via layer VIA1 may be formed at a suitable height (e.g., a predetermined height) so that at least a portion of the plurality of light emitting elements LE, for example, the second semiconductor layer SEM2, may protrude above the first via layer VIA1. In other words, the height of the first via layer VIA1 may be shorter than the height of the light emitting element LE.

The first via layer VIA1 may include an organic material to flatten the lower step. For example, the first via layer VIA1 may include a polyacrylates resin, an epoxy resin, a phenolic resin, a polyamides resin, a polyimides rein, unsaturated polyesters resin, poly phenylenethers resin, polyphenylenesulfides resin, and/or benzocyclobutene (BCB) resin.

The common electrode CE may be directly disposed on the top and side surfaces of the plurality of light emitting elements LE. The common electrode CE may directly contact the second semiconductor layer SEM2 exposed on the top surface of the light emitting element LE. The common electrode CE may be disposed to be around (e.g., to surround) the side of the second semiconductor layer SEM2 protruding above the first via layer VIA1. As shown in FIG. 6, the common electrode CE covers the plurality of light emitting elements LE and may be a common layer disposed in common connection with the plurality of light emitting elements LE.

The first insulating layer INS1 disposed on the common electrode CE may include a transparent insulating material, which may transmit the light emitted from the light emitting elements LE. The first insulating layer INS1 may protect the common electrode CE disposed at the bottom.

The second insulating layer INS2 disposed on the partition wall unit PW may include a transparent insulating material and may be formed of the same material as the first insulating layer INS1.

In one or more embodiments, the first partition wall PW1 and the second partition wall PW2 may block the transmission of light in the light non-emitting area NEA. The first partition wall PW1 and the second partition wall PW2 may further include a light blocking material and may include a dye or pigment having light blocking properties. For example, the first partition wall PW1 and the second partition wall PW2 may be a black matrix. External light incident from the outside of the display device 10 may cause a problem that distorts the color gamut of the wavelength control unit 200. According to one or more embodiments, the partition wall unit PW including a light blocking material is disposed in the wavelength control unit 200 so that at least a portion of external light is absorbed by the partition wall unit PW. Therefore, color distortion caused by external light reflection may be reduced. Additionally, the partition wall unit PW including a light-blocking material may prevent light from intruding between adjacent light-emitting areas and causing mixing, thereby further improving the color reproduction rate. The width of the partition wall unit PW may become narrower as it moves from the first partition wall PW1 to the second partition wall PW2. A step may be formed at a point where the first partition wall PW1 and the second partition wall PW2 meet. Although this embodiment illustrates the partition wall unit PW including the first partition wall PW1 and the second partition wall PW2, it is not limited thereto, and the partition wall unit PW may be a single layer.

The second insulating layer INS2 completely surrounds the partition wall unit PW disposed at the bottom and protect the partition wall unit PW.

The second insulating layer INS2 may extend from the side of the first partition wall PW1 to the side of the second partition wall PW2 and may extend from the side of the second partition wall PW2 to the top surface of the second partition wall PW2. The second insulating layer INS2 may be around (e.g., may surround) the side surfaces of the first and second partition walls PW1 and PW2 and cover the top surface of the second partition wall PW2. The second insulating layer INS2 may continuously extend at the contact point between the first partition wall PW1 and the second partition wall PW2.

In one or more embodiments, the reflective layer RF may include the first reflective layer RF1 around (e.g., surrounding) the side of the first partition wall PW1, the second reflective layer RF2 around (e.g., surrounding) the side of the second partition wall PW2, the third reflective layer RF3 disposed on a flat surface between the partition wall unit PW and the light emitting element LE, and the fourth reflective layer RF4 around (e.g., surrounding) the side of the light emitting element LE protruding upwardly from the first via layer VIA1.

The first reflective layer RF1 and the second reflective layer RF2 are around (e.g., surround) the side of the partition wall unit PW, but the first reflective layer RF1 and the second reflective layer RF2 may be cut off from each other (e.g., may be spaced from each other) if the first partition wall PW1 and the second partition wall PW2 form a step. The third reflective layer RF3 may be disposed between the first reflective layer RF1 and the fourth reflective layer RF4 on the first insulating layer INS1. The first reflective layer RF1, the third reflective layer RF3, and the fourth reflective layer RF4 may be connected continuously. In one or more embodiments where the light emitting element LE protruding from the first insulating layer INS1 to the top of the second via layer VIA2, the fourth reflective layer RF4 may be around (e.g., may surround) at least a portion of the side of the second semiconductor layer SEM2. The distance between the fourth reflective layer RF4, that is, the sidewall of the light emitting element LE, and the first partition wall PW1 may be about 4 μm but is not limited thereto. The reflective layer RF may be disposed on the inner side of the wavelength conversion layer QDL between the partition wall unit PW, excluding the top surface of the light emitting element LE.

As shown in FIG. 9, the reflective layer RF may be disposed to correspond to and overlap each of the light emitting areas EA1, EA2, and EA3. The reflective layer RF disposed in each light emitting area EA1, EA2, and EA3 may be spaced from the reflective layer RF disposed in the adjacent light emitting area EA1, EA2, and EA3. The reflective layer RF may include a plurality of holes disposed in areas corresponding to the light emitting elements LE on a plane. That is, the reflective layer RF may not be formed in the area corresponding to each light emitting element LE.

The reflective layer RF may reflect light emitted from the light emitting element LE. For example, the first reflective layer RF1, the second reflective layer RF2, and the fourth reflective layer RF4 may reflect light emitted from the active layer MQW of the light emitting element LE to the side to the top (e.g., in the third direction DR3). The third reflective layer RF3 may reflect light incident on the third reflective layer RF3 that is reflected by the first reflective layer RF1, the second reflective layer RF2, and the fourth reflective layer RF4 and may not be reflected upward (e.g., in the third direction DR3). In other words, the reflective layer RF may improve the light emission efficiency of the light emitting element LE.

In one or more embodiments, as shown in FIG. 9, a single light emitting element LE may be disposed on a single pixel electrode PE1, PE2, and PE3. On the other hand, as shown in FIG. 10, the plurality of light emitting elements LE may be disposed on one pixel electrode PE1, PE2, and PE3.

The second via layer VIA2, the deterioration prevention layer QBANK, and the wavelength conversion layer QDL may be sequentially disposed in turn in the space in the light emitting area EA1 formed by the partition wall unit PW.

The second via layer VIA2 may flatten the step of the light emitting element LE. The second via layer VIA2 has an opening OP exposing the first insulating layer INS1 disposed on the light emitting element LE. The second via layer VIA2 is not disposed on the top of the light emitting element LE.

The height of the second via layer VIA2 may be lower than the height of the deterioration prevention layer QBANK. The second via layer VIA2 may include the same material as the first via layer VIA1. For example, the second via layer VIA2 may include a polyacrylates resin, an epoxy resin, a phenolic resin, a polyamides resin, a polyimides rein, unsaturated polyesters resin, poly phenylenethers resin, polyphenylenesulfides resin, and/or benzocyclobutene (BCB) resin.

The deterioration prevention layer QBANK is disposed on the second via layer VIA2 and the light emitting element LE and may be in direct contact with the second via layer VIA2 and the first insulating layer INS1 on the light emitting element LE. The deterioration prevention layer QBANK prevents heat generated from the light emitting element LE from being directly transferred to the wavelength conversion layer QDL. The wavelength conversion layer QDL may be in direct contact with the deterioration prevention layer QBANK. The thickness h1 of the deterioration prevention layer QBANK may be less than the thickness h2 of the wavelength conversion layer QDL.

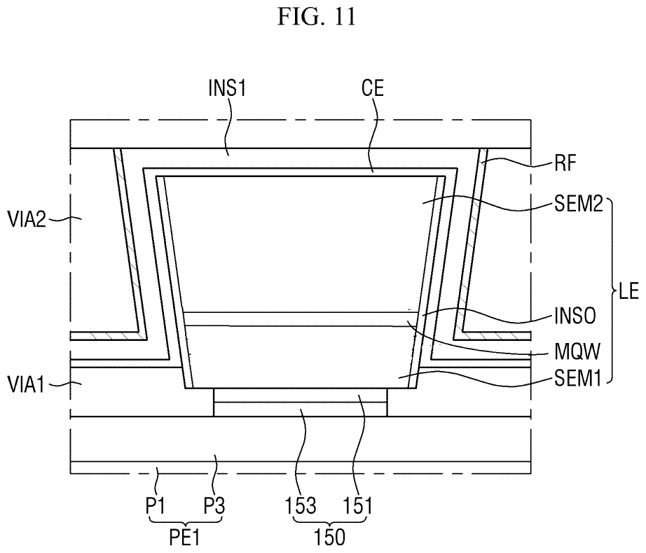

FIG. 11 is a cross-sectional view of a pixel electrode and a light emitting element according to one or more embodiments.

Referring to FIG. 11, the first via layer VIA1 differs from the embodiments of FIGS. 6-10 above in that the active layer MQW of the light emitting element LE protrudes to the top of the first via layer VIA1. Hereinafter, descriptions overlapping with the above-described embodiment will be omitted and differences will be described.

The active layer MQW and the second semiconductor layer SEM2 may protrude onto the top of the first via layer VIA1, and at least a portion of the first semiconductor layer SEM1 may further protrude from the top of the first via layer VIA1.

Therefore, the common electrode CE and the first insulating layer INS1 may be disposed to be around (e.g., to surround) the top surface of the second semiconductor layer SEM2, the side of the second semiconductor layer SEM2, the side of the active layer MQW, and at least a portion of the side of the first semiconductor layer SEM1.

Additionally, the reflective layer RF may be disposed to be around (e.g., to surround) the side of the second semiconductor layer SEM2, the side of the active layer MQW, and at least a portion of the side of the first semiconductor layer SEM1 of the light emitting element LE.

The reflective layer RF is disposed to be around (e.g., to surround) the side of the active layer MQW that emits light, so that the light emission efficiency of the light emitting element LE may be further improved.

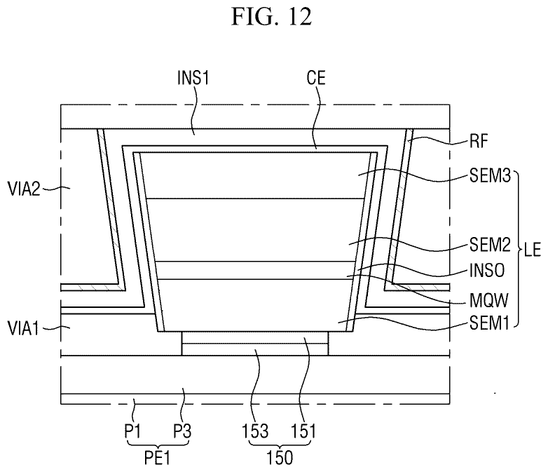

FIG. 12 is a cross-sectional view of a pixel electrode and a light emitting element according to one or more embodiments.

Referring to FIG. 12, the light emitting element LE differs from the embodiment of FIG. 11 above in that the light emitting element LE has the third semiconductor layer SEM3 on the second semiconductor layer SEM2. Hereinafter, descriptions overlapping with the above-described embodiment will be omitted and differences will be described.

The light emitting element LE may include the connection electrode 150, the first semiconductor layer SEM1, the active layer MQW, the second semiconductor layer SEM2, and the third semiconductor layer SEM3 arranged along the thickness direction of the substrate 110, that is, the third direction DR3. The connection electrode 150, the first semiconductor layer SEM1, the active layer MQW, the second semiconductor layer SEM2, and the third semiconductor layer SEM3 may be stacked sequentially along the third direction DR3. The light emitting element LE may include the element insulating layer INS0 around (e.g., surrounding) the first semiconductor layer SEM1, the active layer MQW, the second semiconductor layer SEM2, and the third semiconductor layer SEM3.

The third semiconductor layer SEM3 may include the same material as the second semiconductor layer SEM2 but may be a material that is not doped with an n-type or p-type dopant. In one or more embodiments, the third semiconductor layer SEM3 may be at least one of undoped InAlGaN, GaN, AlGaN, InGaN, AlN, and InN but is not limited thereto.

The active layer MQW, the second semiconductor layer SEM2, and the third semiconductor layer SEM3 may protrude onto top of the first via layer VIA1, and at least a portion of the first semiconductor layer SEM1 may further protrude onto top of the first via layer VIA1.

The common electrode CE and the first insulating layer INS1 may be disposed to be around (e.g., to surround) the top surface of the third semiconductor layer SEM3, the side of the third semiconductor layer SEM3, the side of the second semiconductor layer SEM2, the side of the active layer MQW, and at least a portion of the side of the first semiconductor layer SEM1.

Additionally, the reflective layer RF may be disposed to be around (e.g., to surround) the side of the third semiconductor layer SEM3, the side of the second semiconductor layer SEM2, the side of the active layer MQW, and at least a portion of the side of the first semiconductor layer SEM1 of the light emitting element LE.

The reflective layer RF may be arranged to be around (e.g., to surround) the side of the active layer MQW that emits light, so that the light emission efficiency of the light emitting element LE may be further improved.

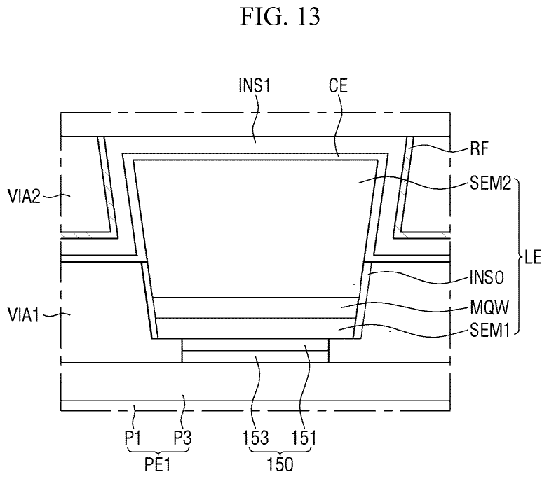

FIG. 13 is a cross-sectional view of a pixel electrode and a light emitting element according to one or more embodiments.

Referring to FIG. 13, it differs from the embodiments of FIGS. 6-10 above in that the element insulating layer INS0 is disposed only on a portion of the side of the light emitting element LE. Hereinafter, descriptions overlapping with the above-described embodiment will be omitted and differences will be described.

The element insulating layer INS0 is disposed on the side of the first semiconductor layer SEM1 and the active layer MQW and may be disposed on a portion of the side of the second semiconductor layer SEM2. That is, the element insulating layer INS0 may expose at least a portion of the second semiconductor layer SEM2.

The side of the second semiconductor layer SEM2 on which the element insulating layer INS0 is not disposed may be directly contacted to the common electrode CE.

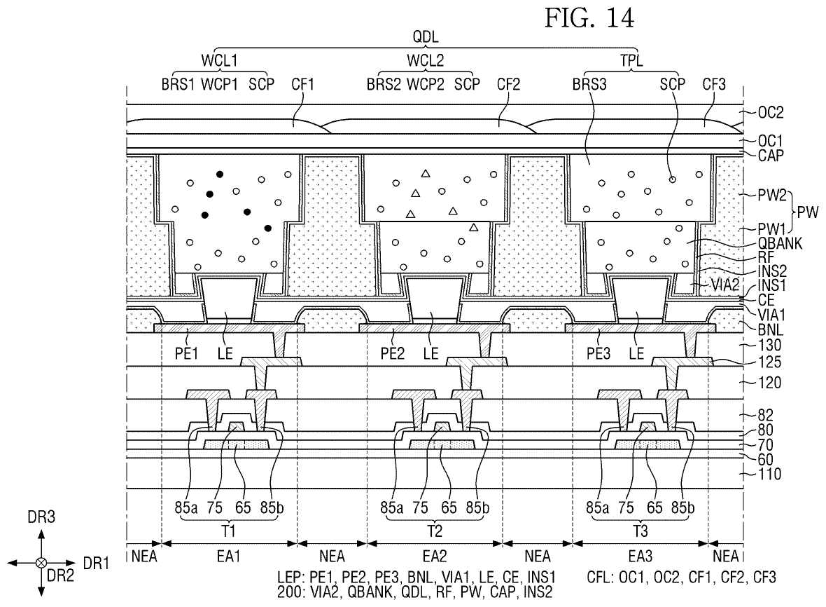

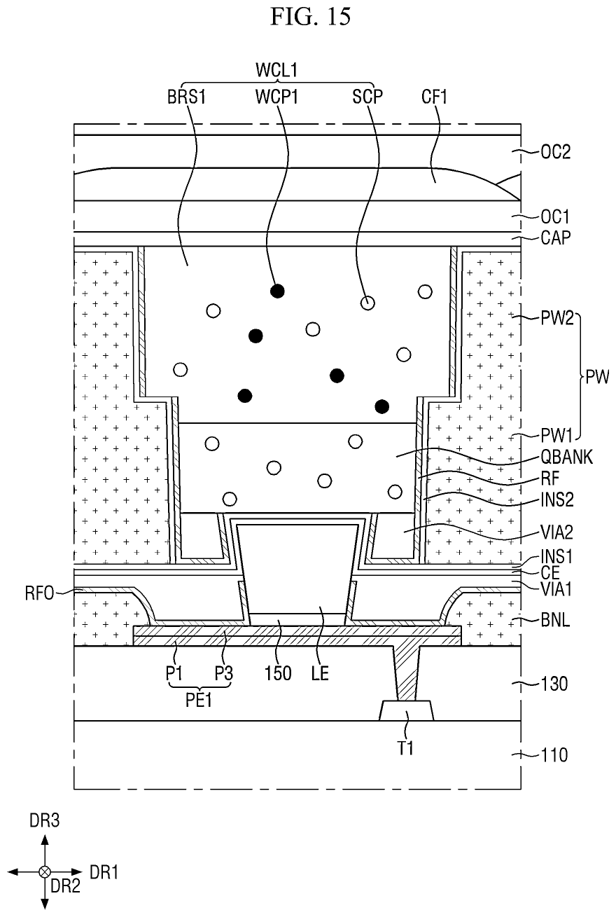

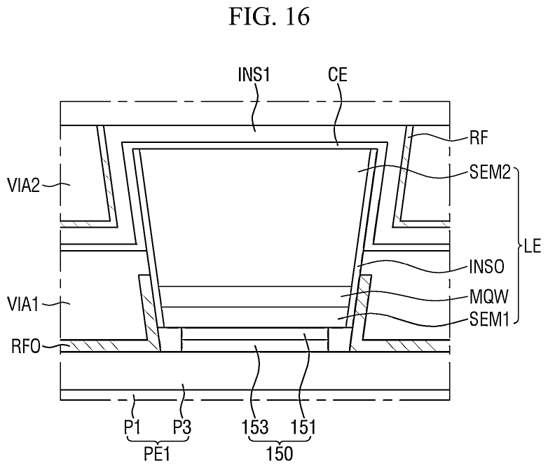

FIG. 14 is a cross-sectional view schematically illustrating a display device according to one or more embodiments. FIG. 15 is an enlarged view schematically illustrating the first light emitting area described with reference to FIG. 14. FIG. 16 is a cross-sectional view illustrating a pixel electrode and a light emitting element according to one or more embodiments described with reference to FIG. 14.

Referring to FIGS. 14 to 16, the display device differs from the embodiment of FIGS. 6-10 described above in that it further includes an element reflective layer RF0 around (e.g., surrounding) the side of the light emitting element. Hereinafter, descriptions overlapping with the above-described embodiment will be omitted and differences will be described.

The element reflective layer RF0 may be disposed on each pixel electrode PE1, PE2, and PE3 and the bank BNL. The element reflective layer RF0 may be disposed to be around (e.g., to surround) the side of the light emitting element LE. For example, the element reflective layer RF0 may be around (e.g., may surround) the outer surface (e.g., the outer peripheral or circumferential surface) of the light emitting element LE and may be around (e.g., may surround) the sides of the first semiconductor layer SEM1, the active layer MQW, and the second semiconductor layer SEM2 of the light emitting element LE. The element reflective layer RF0 may completely surround the sides of the first semiconductor layer SEM1 and the active layer MQW of the light emitting element LE and may be around (e.g., may surround) at least a portion of the sides of the second semiconductor layer SEM2. The element reflective layer RF0 may extend from the top surface of each pixel electrode PE1, PE2, and PE3 in the third direction DR3 to be around (e.g., surround) the light emitting elements LE but may be disposed lower than the height of the light emitting elements LE. In one or more embodiments, an interlayer insulating layer (e.g., the element insulating layer INS0) may be further disposed between the element reflective layer RF0 and each pixel electrode PE1, PE2, and PE3. The interlayer insulating layer (e.g., the element insulating layer INS0) may insulate between the element reflective layer RF0 and each pixel electrode PE1, PE2, and PE3. The element reflective layer RF0 may be disposed in direct contact with the element insulating layer INS0 of the light emitting element LE.

The element reflective layer RF0 may reflect light emitted from the light emitting element LE. For example, the element reflective layer RF0 may reflect light emitted from the active layer MQW of the light emitting element LE to the side toward the top (e.g., in the third direction DR3). That is, the element reflective layer RF0 may improve the light emission efficiency of the light emitting element LE. To this end, the element reflective layer RF0 may be arranged to be around (e.g., to surround) at least the side of the active layer MQW of the light emitting element LE. The height of the element reflective layer RF0 in contact with the light emitting element LE may be less than the height of the light emitting element LE (e.g., at least 50% of the height of the light emitting element LE). For example, if the height of the light emitting element LE is 10 μm, the height of the element reflective layer RF0 may be 5 μm or more and 10 μm or less. Accordingly, the element reflective layer RF0 may be arranged to be around (e.g., surround) the entire side of the active layer MQW of the light emitting element LE and may reflect light emitted from the active layer MQW.

The element reflective layer RF0 may include a metal material with high reflectivity. For example, the element reflective layer RF0 may include aluminum and/or silver and/or may be an alloy thereof.

The element reflective layer RF0 disposed in each light emitting area EA1, EA2, and EA3 may be spaced from the element reflective layer RF0 disposed in the adjacent light emitting areas EA1, EA2, and EA3. Additionally, the element reflective layer RF0 may include a plurality of holes disposed in regions corresponding to the planar light emitting elements LE. That is, the element reflective layer RF0 may not be formed in the region corresponding to each light emitting element LE.

The display device 10 according to the present embodiment may reflect light emitted from the light emitting element LE to the top by including the element reflective layer RF0 around (e.g., surrounding) the side of the light emitting element LE. Accordingly, the element reflective layer RF0 may improve the light emission efficiency of the light emitting element LE.

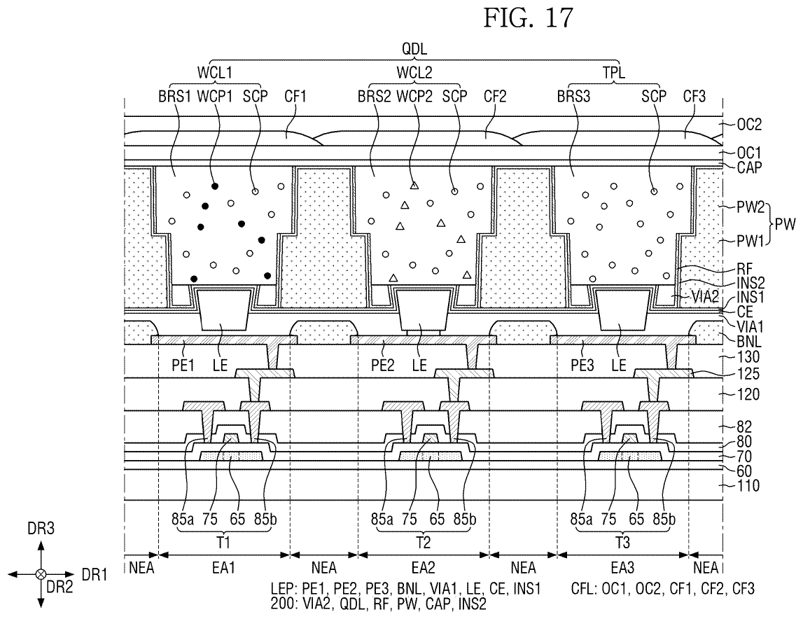

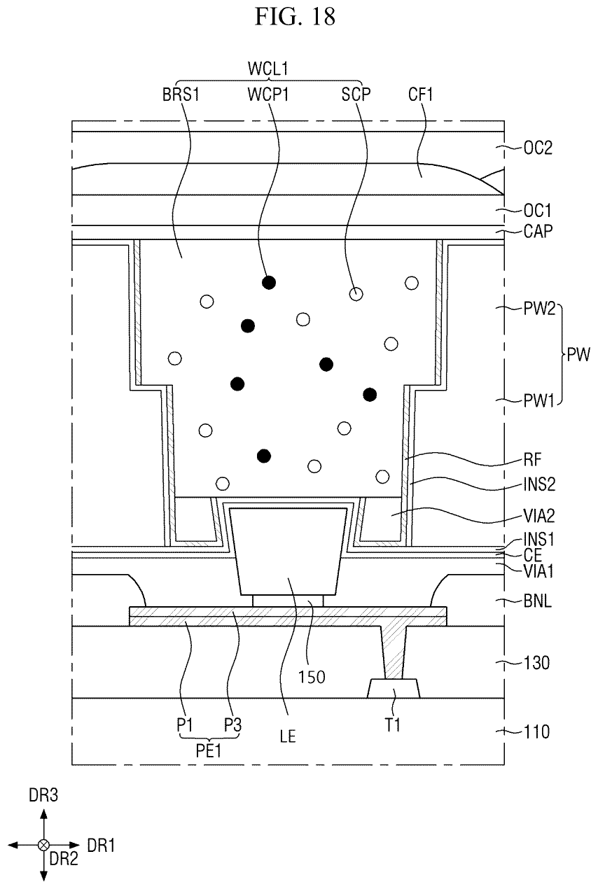

FIG. 17 is a cross-sectional view schematically illustrating a display device according to one or more embodiments. FIG. 18 is an enlarged view schematically illustrating the first light emitting area described with reference to FIG. 17.

Referring to FIGS. 17 and 18, the wavelength control unit 200 differs from the embodiments of FIGS. 6-10 described above in that it does not include the deterioration prevention layer QBANK. Hereinafter, descriptions overlapping with the above-described embodiment will be omitted and differences will be described.

The wavelength control unit 200 may include the second via layer VIA2, the wavelength conversion layer QDL, the second insulating layer INS2, the reflection layer RF, and the partition wall unit PW.

The second via layer VIA2 and the wavelength conversion layer QDL may be sequentially disposed in the space overlapping each of the light emitting areas EA1, EA2, and EA3 and formed by the partition wall unit PW. That is, the wavelength conversion layer QDL may be disposed to be in contact with the second via layer VIA2 and the first insulating layer INS1 on the common electrode CE.

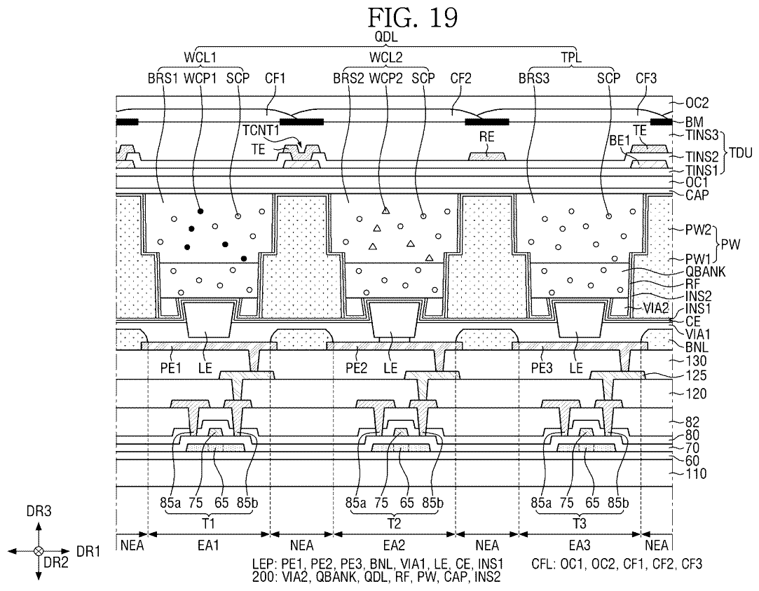

FIG. 19 is a cross-sectional view schematically illustrating a display device according to one or more embodiments. FIG. 20 is an enlarged layout view illustrating in detail one example of the touch node described with reference to FIG. 19.

Referring to FIGS. 19 and 20, the display device is different from the embodiments of FIGS. 6-10 above in that the display device further includes a touch detection unit TDU, and a light blocking pattern BM is further disposed below the color filters CF1, CF2, and CF3. Hereinafter, descriptions overlapping with the above-described embodiment will be omitted and differences will be described.

The touch detection unit TDU may be disposed between the first overcoat layer OC1 and the color filters CF1, CF2, and CF3.

The touch detection unit TDU includes a first touch insulating layer TINS1, a first connection unit BE1, a second touch insulating layer TINS2, a driving electrode TE, a sensing electrode RE, and a third touch insulating layer TINS3.

The first touch insulating layer TINS1 may be formed of an inorganic layer, for example, a silicon nitride layer, a silicon oxynitride layer, a silicon oxide layer, a titanium oxide layer, and/or an aluminum oxide layer.

The first connection unit BE1 may be disposed on the first touch insulating layer TINS1. The first connection unit BE1 may be formed as a single layer or multiple layers of one or more of molybdenum (Mo), aluminum (Al), chromium (Cr), gold (Au), titanium (Ti), nickel (Ni), neodymium (Nd), and copper (Cu), and/or an alloy thereof.

The second touch insulating layer TINS2 is disposed on the first connection unit BE1. The second touch insulating layer TINS2 may be formed of an inorganic layer, for example, a silicon nitride layer, a silicon oxynitride layer, a silicon oxide layer, a titanium oxide layer, and/or an aluminum oxide layer. Alternatively, the second touch insulating layer TINS2 may be formed from an organic film, such as an acrylic resin, an epoxy resin, a phenolic resin, a polyamide resin, a polyimide resin, and/or the like.

The driving electrodes TE and the sensing electrodes RE may be disposed on the second touch insulating layer TINS2. In addition to the driving electrodes TE and the sensing electrodes RE, dummy patterns, first touch driving lines, second touch driving lines, and touch sensing lines may be disposed on the second touch insulating layer TINS2. The driving electrodes TE and sensing electrodes RE may be formed as a single layer or multiple layers of one or more of molybdenum (Mo), aluminum (Al), chromium (Cr), gold (Au), titanium (Ti), nickel (Ni), neodymium (Nd), and copper (Cu), and/or an alloy thereof.

The driving electrode TE and the sensing electrode RE may overlap the first connection unit BE1 in the third direction DR3. The driving electrode TE may be connected to the first connection unit BE1 through a touch contact hole TCNT1 penetrating the second touch insulating layer TINS2.

The third touch insulating layer TINS3 is formed on the driving electrodes TE and the sensing electrodes RE. The third touch insulating layer TINS3 may serve to flatten the steps formed by the driving electrodes TE, the sensing electrodes RE, and the first connection unit BE1. The third touch insulating layer TINS3 may be formed from an organic film such as an acrylic resin, an epoxy resin, a phenolic resin, a polyamide resin, a polyimide resin, or the like.

A touch node TN may be defined as the intersection of the driving electrode TE and the sensing electrode RE.

Because a plurality of driving electrodes TE and the plurality of sensing electrodes RE are disposed in (e.g., at) the same layer, they may be spaced from each other. That is, a gap may be formed between the driving electrode TE and the sensing electrode RE that are adjacent to each other.

Further, a plurality of dummy patterns may also be disposed on (e.g., at) the same layer as the plurality of driving electrodes TE and the sensing electrodes RE. That is, a gap may be formed between adjacent the driving electrode TE and the dummy pattern and between adjacent the sensing electrode RE and the dummy pattern.

A plurality of first connection units BE1 may be disposed on (e.g., at) a different layer from the plurality of driving electrodes TE and the plurality of sensing electrodes RE. The plurality of first connection units BE1 may be formed to be bent at least once. In FIG. 20, the plurality of first connection units BE1 are illustrated as having a planar shape of an angle bracket (“<” or “>”), but the planar shape of the plurality of first connection units BE1 is not limited to this. Because the driving electrodes TE adjacent to each other in the second direction DR2 are connected by the plurality of first connection units BE1, the connection between the driving electrodes TE adjacent to each other in the second direction DR2 may be maintained even if any of the plurality of first connection units BE1 is disconnected. Although FIG. 20 illustrates that adjacent driving electrodes TE are connected by two first connection units BE1, the number of first connection units BE1 is not limited to this.

Each of the plurality of first connection units BE1 may overlap adjacent driving electrodes TE in the third direction DR3, which is the thickness direction of the substrate 110. Each of the plurality of first connection units BE1 may overlap the sensing electrode RE in the third direction DR3. One side of the first connection units BE1 may be connected to one of the adjacent driving electrodes TE in the second direction DR2 through the touch contact holes TCNT1. The other side of the first connection unit BE1 may be connected to another driving electrode TE from among adjacent driving electrodes TE in the second direction DR2 through the touch contact holes TCNT1.

Due to the plurality of first connection units BE1, the plurality of driving electrodes TE, and the plurality of sensing electrodes RE may be electrically separated at each of their intersection parts. As a result, mutual capacitance may be formed at each intersection of the plurality of driving electrodes TE and the plurality of sensing electrodes RE.

Each of the plurality of driving electrodes TE, the plurality of sensing electrodes RE, and the plurality of first connection units BE1 may have a planar shape of a mesh structure or a mesh structure. Additionally, each of the plurality of dummy patterns may have a planar shape of a mesh structure or a mesh structure. As a result, each of the plurality of driving electrodes TE, the plurality of sensing electrodes RE, the plurality of first connection units BE1, and the plurality of dummy patterns may not overlap with the plurality of light emitting areas EA1, EA2, EA3, and EA4 of each of the plurality of pixels PX. Therefore, the light emitted from the plurality of light emitting areas EA1, EA2, and EA3, and EA4 may not be blocked by the plurality of driving electrodes TE, the plurality of sensing electrodes RE, the plurality of first connection units BE1, and the plurality of dummy patterns to prevent the luminance of the light from being reduced.

Each of the plurality of pixels PX includes a first light emitting area EA1 that emits light of a first color, a second light emitting area EA2 that emits light of a second color, a third light emitting area EA3 that emits light of a third color, and a fourth light emitting area EA4 that emits light of a second color. For example, the first color may be red, the second color may be green, and the third color may be blue.

In this embodiment, a single pixel PX includes four light emitting areas EA1, EA2, EA3, and EA4, but it is not limited thereto.

FIG. 19 may be an example of a display panel cut along the line I-I′ of FIG. 20.

In one or more embodiments, the first light emitting area EA1 and the second light emitting area EA2 of each of the plurality of pixels PX may be adjacent to each other in the fourth direction DR4, and the third light emitting area EA3 and the fourth light emitting area EA4 may be adjacent to each other in the fourth direction DR4. The first light emitting area EA1 and the fourth light emitting area EA4 of each of the plurality of pixels PX may be adjacent to each other in the fifth direction DR5, and the second light emitting area EA2 and the third light emitting area EA3 may be adjacent to each other in the fifth direction DR5.

Each of the first light emitting area EA1, the second light emitting area EA2, the third light emitting area EA3, and the fourth light emitting area EA4 may have a planar shape of a rhombus or a rectangular planar shape but is not limited thereto. Each of the first light emitting area EA1, the second light emitting area EA2, the third light emitting area EA3, and the fourth light emitting area EA4 may have a polygonal other than a square, circular, and/or oval elliptical planar shape. In addition, FIG. 20 illustrates that the first light emitting area EA1, the second light emitting area EA2, the third light emitting area EA3, and the fourth light emitting area EA4 have the same area but is not limited thereto.

The second light emitting areas EA2 and the fourth light emitting areas EA4 may be arranged in odd rows. The second light emitting areas EA2 and the fourth light emitting areas EA4 may be arranged side by side in the first direction DR1 in each of the odd rows. The second light emitting areas EA2 and the fourth light emitting areas EA4 may be alternately arranged in each odd row. Each of the second light emitting areas EA2 may have a short side in the fourth direction DR4 and a long side in the fifth direction DR5, while each of the fourth light emitting areas EA4 may have a long side in the fourth direction DR4 and a short side in the fifth direction DR5. The fourth direction DR4 is a direction between the first direction DR1 and the second direction DR2 which may be a direction inclined at 45 degrees relative to the first direction DR1. The fifth direction DR5 may be a direction orthogonal to the fourth direction DR4.

The first light emitting areas EA1 and the third light emitting areas EA3 may be arranged in even rows. The first light emitting areas EA1 and the third light emitting areas EA3 may be arranged side by side in the first direction DR1 in each of the even-numbered rows. The first light emitting areas EA1 and the third light emitting areas EA3 may be alternately arranged in each even-numbered row.

The second light emitting areas EA2 and the fourth light emitting areas EA4 may be arranged in odd-numbered columns. The second light emitting areas EA2 and the fourth light emitting areas EA4 may be arranged side by side in the second direction DR2 in each of the odd-numbered columns. The second light emitting areas EA2 and the fourth light emitting areas EA4 may be alternately arranged in each odd-numbered column.

The first light emitting areas EA1 and the third light emitting areas EA3 may be arranged in even-numbered columns. The first light emitting areas EA1 and the third light emitting areas EA3 are arranged side-by-side in the second direction DR2 in each of the even-numbered columns. The first light emitting areas EA1 and the third light emitting areas EA3 may be arranged alternately in each of the even-numbered columns.

In one or more embodiments, the light blocking pattern BM may be further included between the touch detection unit TDU and the color filters CF1, CF2, and CF3. The light blocking pattern BM may be formed of a photosensitive resin capable of blocking light. For example, the light blocking pattern BM may include an inorganic black pigment such as carbon black or an organic black pigment. The light blocking pattern BM may overlap the light non-emitting area NEA and not the light emitting areas EA1, EA2, and EA3. Therefore, even if the light emitted from the light emitting element LE travels to the light blocking pattern BM, it does not pass through the light blocking pattern BM. Accordingly, the light blocking pattern BM may prevent color mixing between adjacent light emitting areas.

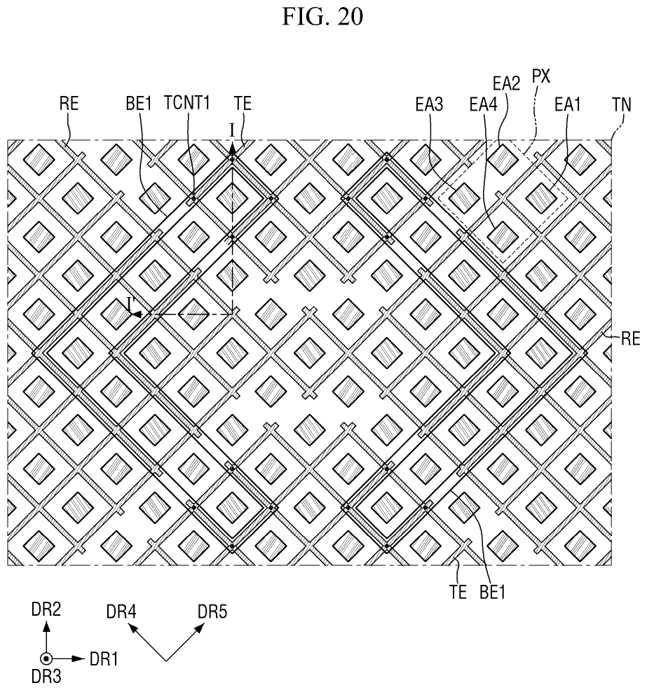

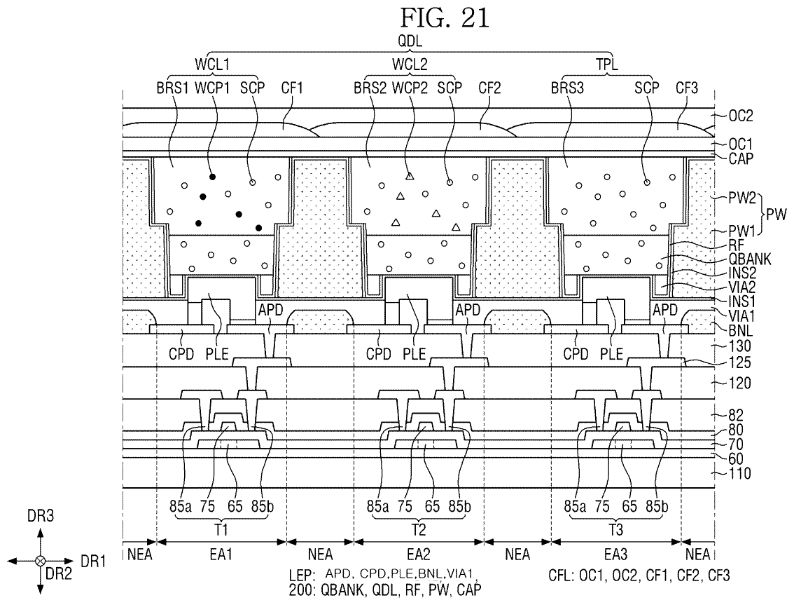

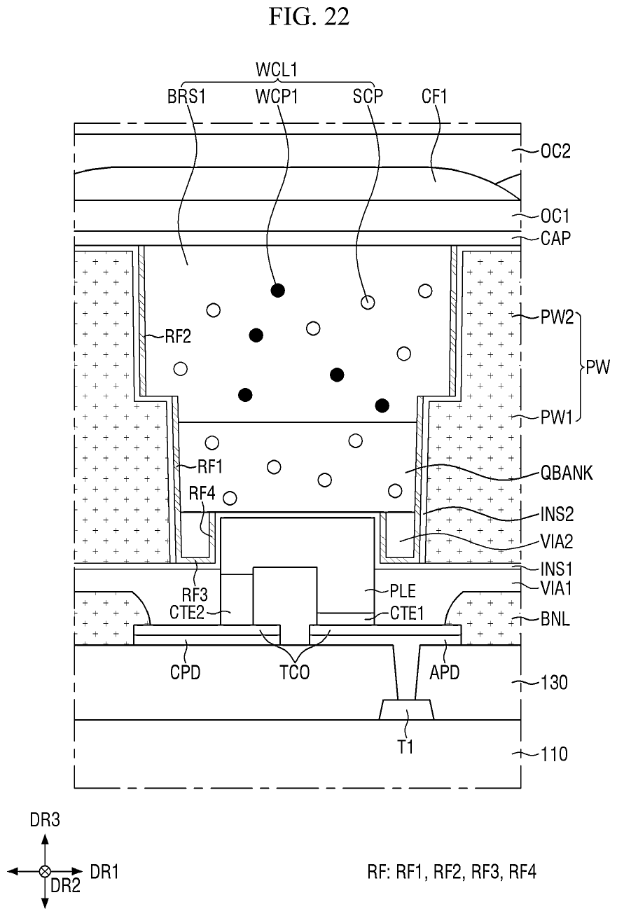

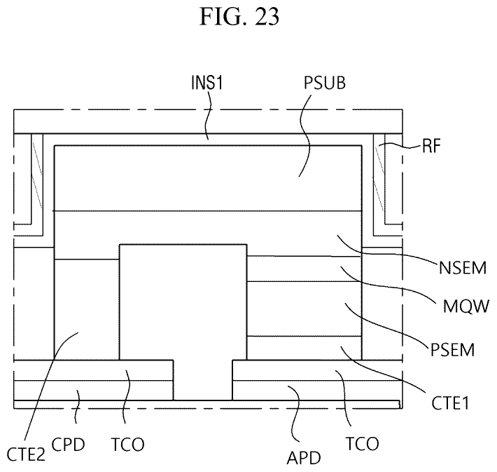

FIG. 21 is a cross-sectional view schematically illustrating a display device according to one or more embodiments. FIG. 22 is an enlarged view schematically illustrating the first light emitting area described with reference to FIG. 21. FIG. 23 is a cross-sectional view illustrating a pixel electrode and a light emitting element according to one or more embodiments described with reference to FIG. 22.

Referring to FIGS. 21 to 23, a light emitting element PLE is different from the embodiments of FIGS. 6-10 described above in that the light emitting element PLE is a flip-chip type light emitting element, and an anode pad electrode APD and a cathode pad electrode CPD are disposed in place of the pixel electrodes PE1, PE2, and PE3 and the common electrode CE. Hereinafter, descriptions overlapping with the above-described embodiment will be omitted and differences will be described.

The anode pad electrode APD and the cathode pad electrode CPD may be disposed on the second planarization layer 130.

The function of the anode pad electrode APD corresponds to the pixel electrodes PE1, PE2, and PE3 described with reference to FIGS. 6-10, and the function of the cathode pad electrode CPD correspond to the common electrode CE described with reference to FIGS. 6-10.

The anode pad electrode APD and the cathode pad electrode CPD may be disposed in each light emitting area EA1, EA2, and EA3. The anode pad electrode APD and the cathode pad electrode CPD disposed in each light emitting area EA1, EA2, and EA3 may be spaced from each other.

The anode pad electrode APD and the cathode pad electrode CPD may be formed as a single layer or multiple layers of one or more of molybdenum (Mo), aluminum (Al), chromium (Cr), gold (Au), titanium (Ti), nickel (Ni), neodymium (Nd), and copper (Cu), and/or an alloy thereof.

The anode pad electrode APD is directly connected to the pixel connection electrode 125 through a contact hole penetrating the second planarization layer 130 and may be electrically connected to each of the switching elements T1, T2, and T3 through the pixel connection electrode 125.

The cathode pad electrode CPD may be supplied with a first power supply voltage that is a low potential voltage.

A transparent conductive layer TCO may be included on each of the anode pad electrode APD and the cathode pad electrode CPD to enhance adhesion to a first contact electrode CTE1 and a second contact electrode CTE2 of a flip-chip light emitting element PLE. The transparent conductive layer TCO may be formed of a transparent conductive oxide such as indium tin oxide (ITO) and/or indium zinc oxide (IZO).

The flip-chip light emitting element PLE is a flip-chip type micro LED in which the first contact electrode CTE1 and the second contact electrode CTE2 are disposed opposite the anode pad electrode APD and the cathode pad electrode CPD.

The flip-chip light emitting element PLE may be an inorganic light emitting element made of an inorganic material such as GaN. The flip-chip light emitting element PLE may have a length in the first direction DR1, a length in the second direction DR2, and a length in the third direction DR3 of several to hundreds of μm, respectively. For example, the flip-chip light emitting element PLE may be 10 μm×25 μm but is not limited to this.

The flip-chip light emitting elements PLE may be formed by growing on a semiconductor substrate, such as a silicon wafer. Each of the flip-chip light emitting element PLE may be directly transferred from the silicon wafer onto the anode pad electrode APD and the cathode pad electrode CPD of the substrate 110. Alternatively, each of the flip-chip light emitting elements PLE may be transferred onto the anode pad electrodes APD and the cathode pad electrodes CPD of substrate 110 by electrostatic methods using an electrostatic head or by stamping methods using an elastic polymer material such as PDMS or silicon as a transfer substrate.

The first contact electrode CTE1 and the anode pad electrode APD may be bonded to each other through a conductive adhesive member such as an anisotropic conductive film (ACF) or anisotropic conductive paste (ACP). Alternatively, the first contact electrode CTE1 and the anode pad electrode APD may be bonded to each other through a soldering process.

The flip-chip light emitting elements PLE may be a light-emitting structure including a base substrate PSUB, an n-type semiconductor NSEM, the active layer MQW, a p-type semiconductor PSEM, the first contact electrode CTE1, and the second contact electrode CTE2.

The base substrate PSUB of the flip-chip light emitting elements PLE may be a sapphire substrate but is not limited thereto.

The n-type semiconductor NSEM of the flip-chip light emitting elements PLE may be disposed on one side of the base substrate PSUB. For example, the n-type semiconductor NSEM may be disposed on the bottom surface of the base substrate PSUB. The n-type semiconductor NSEM may be made of GaN doped with an n-type conductive dopant such as Se, Si, Ge, and/or Sn. The n-type semiconductor NSEM corresponds to the second semiconductor layer SEM2 of the light emitting element LE described with reference to FIGS. 6-10.

The active layer MQW of the flip-chip light emitting elements PLE may be disposed on a portion of one surface of the n-type semiconductor NSEM. The active layer MQW may include a material with a single or multiple quantum well structure. When the active layer MQW includes a material with a multi-quantum well structure, it may be a stacked structure with a plurality of well layers and barrier layers alternating with each other. In this case, the well layer may be formed of InGaN, and the barrier layer may be formed of GaN or AlGaN but are not limited thereto.

Alternatively, the active layer MQW may be a structure in which semiconductor materials with a large energy band gap and semiconductor materials with a small energy band cap are alternately stacked on top of each other and may include three to five semiconductor materials depending on the wavelength of the light emitted.

The p-type semiconductor PSEM may be disposed on one side of the active layer MQW. The p-type semiconductor PSEM may be made of GaN doped with a p-type conductive dopant such as Mg, Zn, Ca, Sr, Ba, etc. The p-type semiconductor PSEM corresponds to the first semiconductor layer SEM1 of the light emitting element LE described with reference to FIGS. 6-10.

The first contact electrode CTE1 may be disposed on one side of the p-type semiconductor PSEM, and the second contact electrode CTE2 may be disposed on another part of one surface of the n-type semiconductor NSEM. The first contact electrode CTE1 and the second contact electrode CTE2 are not in direct contact with each other. Another part of one surface of the n-type semiconductor NSEM on which the second contact electrode CTE2 is disposed may be disposed away from a part of one surface of the n-type semiconductor NSEM on which the active layer MQW is disposed.

As described with reference to FIGS. 21-23, even in a display device employing a flip-chip light emitting element PLE, the reflective layer RF may be arranged to be around (e.g., to surround) the side of the partition wall unit PW, at least some sides of the n-type semiconductor NSEM, and the bottom surface between the partition wall unit PW and the flip-chip light emitting element PLE on the first insulating layer INS1. As a result, the luminous efficiency of the flip-chip light emitting element PLE may be improved.

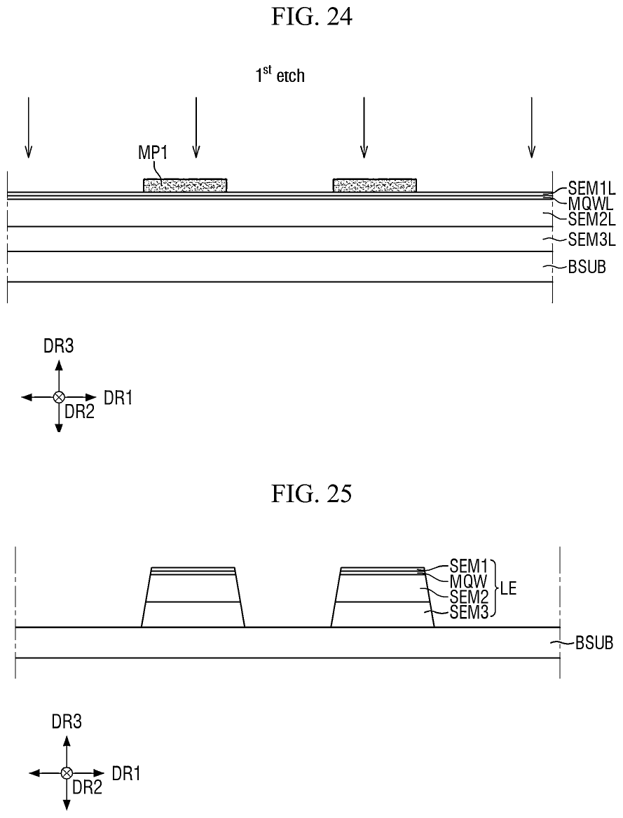

FIGS. 24-43 are diagrams for illustrating a method of manufacturing a display device according to one or more embodiments.

FIGS. 24-43 illustrate the structure of each layer of the display device 10 in the order of formation, respectively in cross-sectional views. FIGS. 24-43 focus on the manufacturing process of the light emitting element unit LEP, which may be roughly corresponding to the cross-sectional views of FIGS. 6-8, respectively. Additionally, the following will focus on the first light emitting area EA1 of the display device 10.

Referring to FIGS. 24 and 25, a plurality of light emitting elements LE are formed on the base substrate BSUB.

Specifically, the base substrate BSUB is prepared. The base substrate BSUB may be a sapphire substrate Al₂O₃ or a silicon wafer including silicon. However, it is not limited thereto, and in one or more embodiments, a case where the base substrate BSUB is a sapphire substrate will be described as an example.

A plurality of semiconductor material layers SEM3L, SEM2L, MQWL, and SEM1L are formed on the base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and/or the like, and preferably formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group such as a methyl or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

Specifically, a third semiconductor material layer SEM3L is formed on the base substrate BSUB. While the drawings illustrate the third semiconductor material layer SEM3L being further stacked, it is not limited to this, and a plurality of layers may be formed. The third semiconductor material layer SEM3L may be disposed to reduce a lattice constant difference between a second semiconductor material layer SEM2L and the base substrate BSUB. For example, the third semiconductor material layer SEM3L may include an undoped semiconductor, which may be an n-type or p-type undoped material. In one or more embodiments, the third semiconductor material layer SEM3L may be at least one of undoped InAlGaN, GaN, AlGaN, InGaN, AlN, and InN but is not limited thereto.

The second semiconductor material layer SEM2L, the active material layer MQWL, and the first semiconductor material layer SEM1L are sequentially formed on the third semiconductor material layer SEM3L by using the above-described method.

Next, a plurality of semiconductor material layers SEM3L, SEM2L, MQWL, and SEM1L are etched to form a plurality of light emitting elements LE.

Specifically, a plurality of first mask patterns MP1 are formed on the first semiconductor material layer SEM1L. The first mask pattern MP1 may be a hard mask containing an inorganic material or a photoresist mask containing an organic material. The first mask pattern MP1 prevents the lower semiconductor material layers SEM3L, SEM2L, MQWL, and SEM1L from being etched. Next, a portion of the plurality of semiconductor material layers is etched using the plurality of first mask patterns MP1 as a mask to form the plurality of light emitting elements LE.

As shown in FIG. 25, on the base substrate BSUB, the plurality of semiconductor material layers SEM3L, SEM2L, MQWL, and SEM1L that are non-overlapping with the first mask pattern MP1 are etched and removed, and a portion that is not etched overlapping with the first mask pattern MP1 may be formed as the plurality of light emitting elements LE.

The semiconductor material layers may be etched by conventional methods. For example, processes for etching semiconductor material layers may be dry etching, wet etching, reactive ion etching (RIE), deep reactive ion etching (DRIE), inductively coupled plasma reactive ion etching (ICP-RIE), and/or the like. In the case of dry etching, anisotropic etching is possible and may be suitable for vertical etching. When using the etching method described above, the etching etchant may be Cl₂ or O₂. However, it is not limited to this.

The plurality of semiconductor material layers SEM3L, SEM2L, MQWL, and SEM1L overlapping the first mask pattern MP1 are not etched and are formed into the plurality of light emitting elements LE. Accordingly, the plurality of light emitting elements LE are formed including a third semiconductor layer SEM3, the second semiconductor layer SEM2, the active layer MQW, and the first semiconductor layer SEM1.

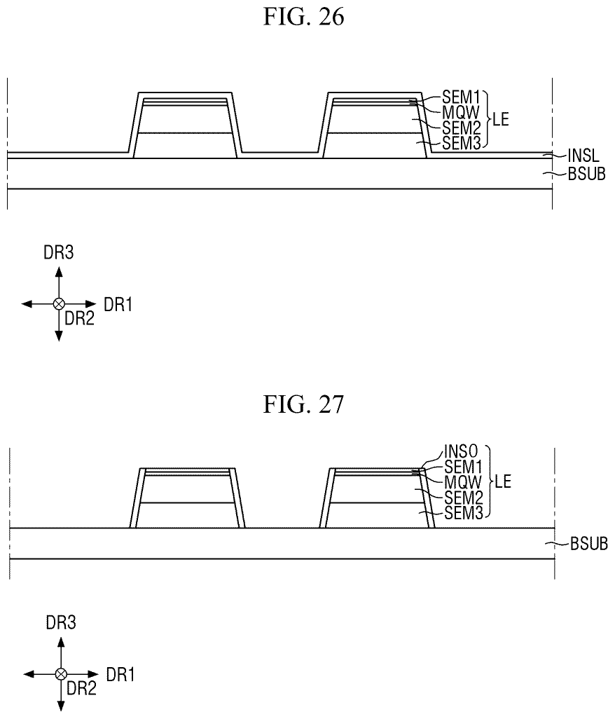

Next, referring to FIGS. 26 and 27, the element insulating layer INS0 is formed on the base substrate BSUB on which the light emitting element LE is formed.

Specifically, the insulating material layer INSL is formed on the outer surface of the plurality of light emitting elements LE. The insulating material layer INSL may be formed on the entire surface of the base substrate BSUB and may be formed not only on the light emitting element LE but also on the top surface of the base substrate BSUB exposed by the light emitting element LE.

Next, a second etch (2^{nd} etch) process is performed to partially remove the insulating material layer INSL to form the light emitting element LE including the element insulating layer INS0.

Specifically, the second etch (2^{nd} etch) process may be performed in which the insulating material layer INSL is partially removed such that the insulating material layer INSL exposes the top surface of the light emitting element LE but encloses the sides of the light emitting element LE. Specifically, a portion of the insulating material layer INSL may be removed to expose the top surface of the first semiconductor layer SEM1 of the light emitting element LE in this process. The process of partially removing the insulating material layer INSL may be performed using anisotropic dry etching or etch-back processes.

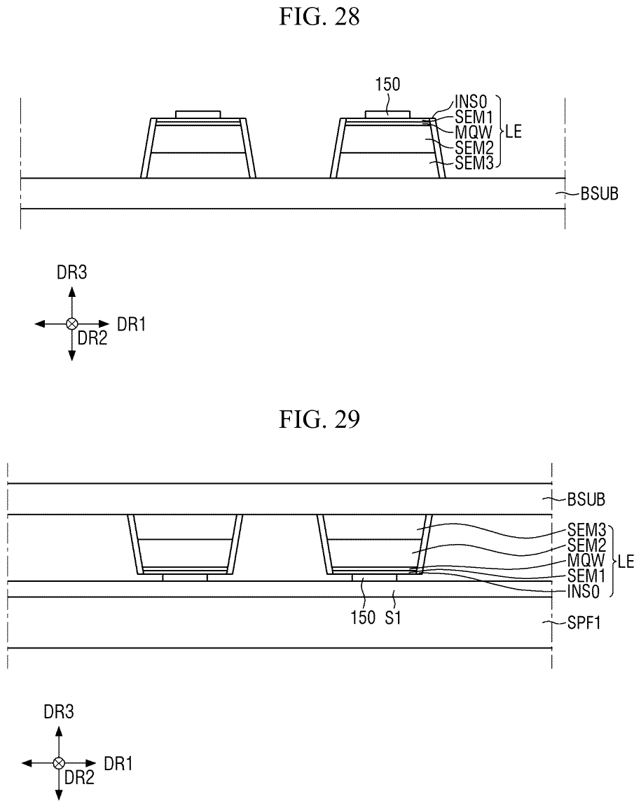

Next, referring to FIG. 28, the connection electrode 150 is formed on the first semiconductor layer SEM1 of the light emitting element LE.

The connection electrode 150 may be formed on the first semiconductor layer SEM1 by stacking an electrode material layer on the base substrate BSUB and then etching it through an etching process. In one or more embodiments, the connection electrode 150 may include the reflective layer (151 in FIG. 8) and the connection layer (153 in FIG. 8).

Next, referring to FIG. 29, the plurality of light emitting elements LE of the base substrate BSUB manufactured in FIG. 28 are attached to a carrier substrate SPF1.

Specifically, the base substrate BSUB is positioned on the carrier substrate SPF1.

The carrier substrate SPF1 may be made of a material that is transparent and mechanically stable so that light may be transmitted. For example, the carrier substrate SPF1 may include a transparent polymer such as polyester, polyacrylic, polyepoxy resin, polyethylene, polystyrene, polyethylene terephthalate, and/or the like.

An adhesive layer S1 having adhesive force may be further disposed on the carrier substrate SPF1. The adhesive layer S1 may include an adhesive material for adhering the light emitting element LE. For example, the adhesive material may include urethane acrylate, epoxy acrylate, polyester acrylate, and/or the like. The adhesive material may be a material whose adhesion changes as ultraviolet rays (UV) or heat is applied, and thus the adhesive layer may be easily separated from the light emitting element LE.

The plurality of light emitting elements LE may be aligned on the adhesive layer S1, and the connection electrodes 150 of the plurality of light emitting elements LE may be attached to the adhesive layer S1. The plurality of light emitting elements LE are arranged in large numbers and may be attached to the carrier substrate SPF1 without being detached from them.

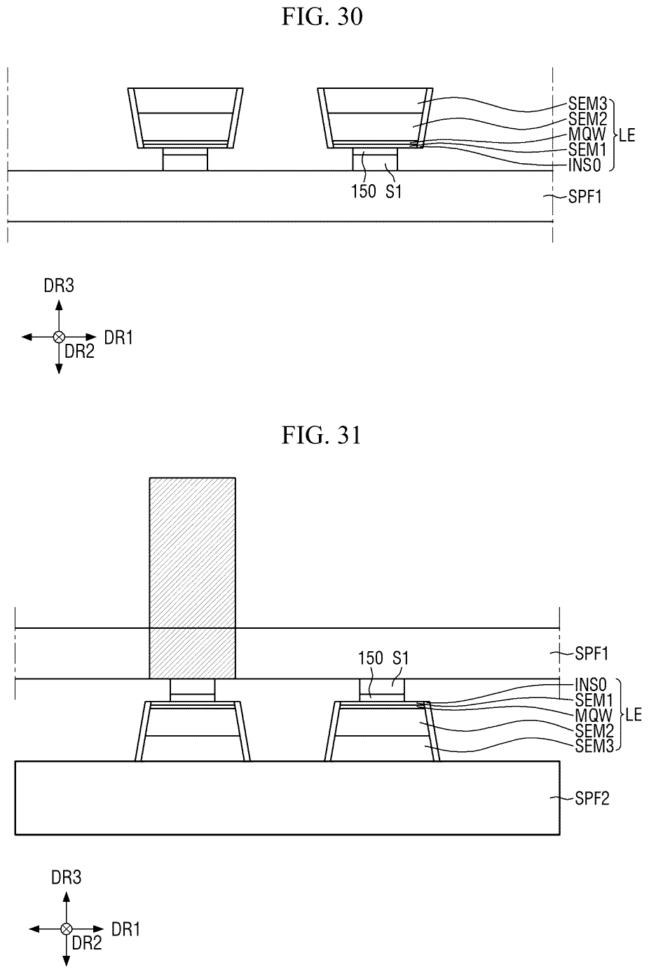

Then, referring to FIG. 30, the base substrate BSUB is irradiated with a first laser to separate the plurality of light emitting elements LE from the base substrate BSUB. The base substrate BSUB is separated from each third semiconductor layer SEM3 of the plurality of light emitting elements LE.

The process for separating the base substrate BSUB may be performed by a laser lift-off (LLO) process. The laser lift-off process utilizes a laser, and a KrF excimer laser (248 nm wavelength) may be used as the source. The energy density of the excimer laser is irradiated in the range of about 550 mJ/cm² to 950 mJ/cm², and the incident area may be in the range of 50×50 μm² to 1×1 cm² but is not limited thereto. The base substrate BSUB may be separated from the plurality of light emitting elements LE by irradiating the base substrate BSUB with the laser. Subsequently, the adhesive layer S1 may be patterned using the light emitting element LE as a mask through an etching process. Afterwards, wet cleaning may be performed to remove residues and debris on the carrier substrate SPF1.

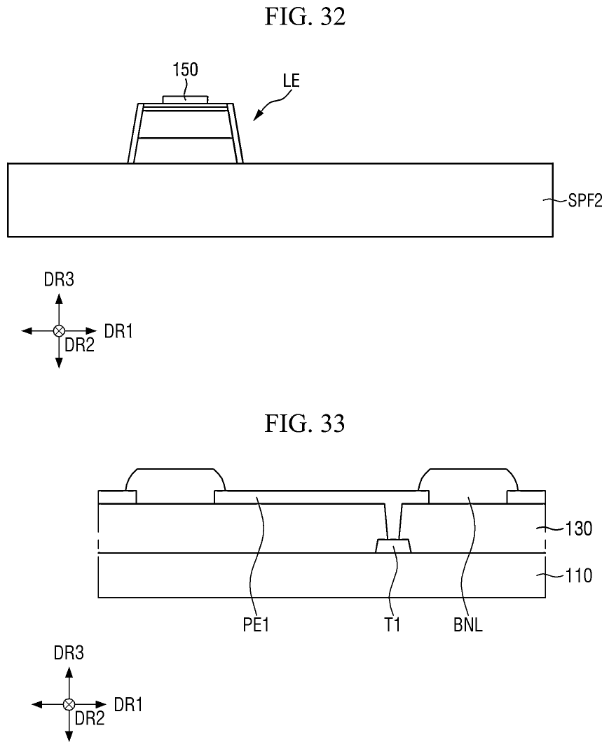

Next, referring to FIGS. 31 and 32, the plurality of light emitting elements LE separated from the base substrate BSUB are selectively transferred to a relay substrate SPF2.

Specifically, the plurality of light emitting elements LE are disposed on the relay substrate SPF2. Each third semiconductor layer SEM3 of the plurality of light emitting elements LE is disposed on the relay substrate SPF2. The relay substrate SPF2 may include a support layer and an adhesive layer. The support layer may be made of a transparent and mechanically stable material that allows light to pass through. For example, the support layer may include transparent polymers such as polyester, polyacrylic, polyepoxy resin, polyethylene, polystyrene, polyethylene terephthalate, and/or the like.

An adhesive layer having adhesive force may be disposed on the support layer. The adhesive layer may include an adhesive material for bonding the light emitting element LE. For example, the adhesive material may include urethane acrylate, epoxy acrylate, polyester acrylate, and/or the like. The adhesive material may be a material whose adhesion changes as ultraviolet rays (UV) or heat is applied, and thus the adhesive layer may be easily separated from the light emitting element LE.

The laser is selectively irradiated to a desired light emitting element LE in consideration of the arrangement spacing of the plurality of light emitting elements LE disposed on the relay substrate SPF2. The adhesion of the adhesive layer attached to the laser-irradiated light emitting element LE may decrease, and the light emitting elements LE may be physically or naturally separated from the carrier substrate SPF1.

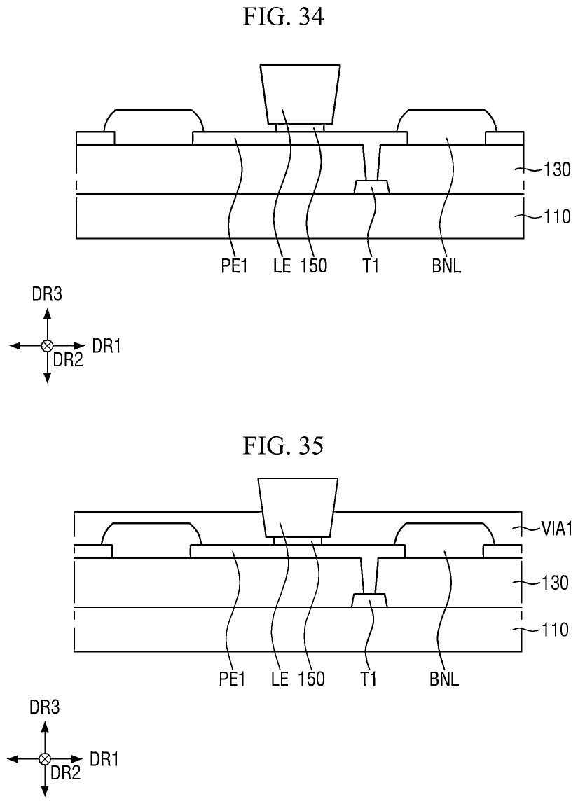

Next, referring to FIGS. 33 and 34, the light emitting element LE on the relay substrate SPF2 is transferred onto the substrate 110.

Specifically, the substrate 110 is prepared. As described with reference to FIG. 6, the substrate 110 may have the pixel electrode PE1 and the bank BNL formed thereon.

The connection electrode 150 of the light emitting element LE disposed on the relay substrate SPF2 is aligned to face the substrate 110.

Next, the substrate 110 and the relay substrate SPF2 are bonded. Specifically, the connection electrode 150 of the light emitting element LE formed on the relay substrate SPF2 are contacted with the pixel electrodes PE1 of the substrate 110. At this time, the connection electrode 150 of the light emitting element LE is in contact with the pixel electrodes PE1. Next, the connection electrode 150 of the light emitting element LE and the pixel electrode PE1 are melt-bonded to bond the substrate 110 and the relay substrate SPF2. At this time, the plurality of light emitting elements LE are attached to the top surfaces of the pixel electrodes PE1.

Melt bonding may be accomplished by irradiating the pixel electrodes PE1 with a laser on top of the relay substrate SPF2. The laser-irradiated pixel electrodes PE1 may conduct the high heat of the laser to bond the interface of the connecting electrode 150 of the light emitting element LE and the pixel electrodes PE1. In particular, the pixel electrodes PE1 may include copper (Cu), which has excellent thermal conductivity, and thus may have excellent adhesion properties with the connection electrode 150 of the light emitting element LE. The source of the laser used for the fusion bonding may be a YAG.

Next, the relay substrate SPF2 is separated from the plurality of light emitting elements LE.

Specifically, the relay substrate SPF2 is separated from the light emitting element LE. The process of separating the relay substrate SPF2 may be done using a laser lift-off (LLO) process. Because the laser lift-off process has been described above, the description will be omitted. By irradiating the laser to the relay substrate SPF2, the relay substrate SPF2 may be separated from the light emitting element LE.

As another example, the process of separating the relay substrate SPF2 may be physically separated in addition to the laser lift-off process. Because the bonding force between the relay substrate SPF2 and the light emitting element LE is smaller than the melt-bonded bonding force between the connection electrode 150 of the light emitting element LE and the pixel electrode PE1, the relay substrate SPF2 may be physically separated based on the difference in bonding force. At this time, the third semiconductor layer SEM3 of the light emitting element LE has low conductivity and may be removed for connection to the common electrode CE. The third semiconductor layer SEM3 may be removed using a dry etching process.

Next, referring to FIG. 35, the first via layer VIA1 is formed on the substrate 110 on which the light emitting elements LE are formed.

Specifically, the first via layer VIA1 may be formed on the pixel electrode PE1 and the bank BNL. The first via layer VIA1 may be applied using a solution process such as spin coating or inkjet printing, or the like. The first via layer VIA1 may be formed lower than the height of the light emitting element LE. For example, the first via layer VIA1 may be formed to a height greater than the height of the active layer MQW.

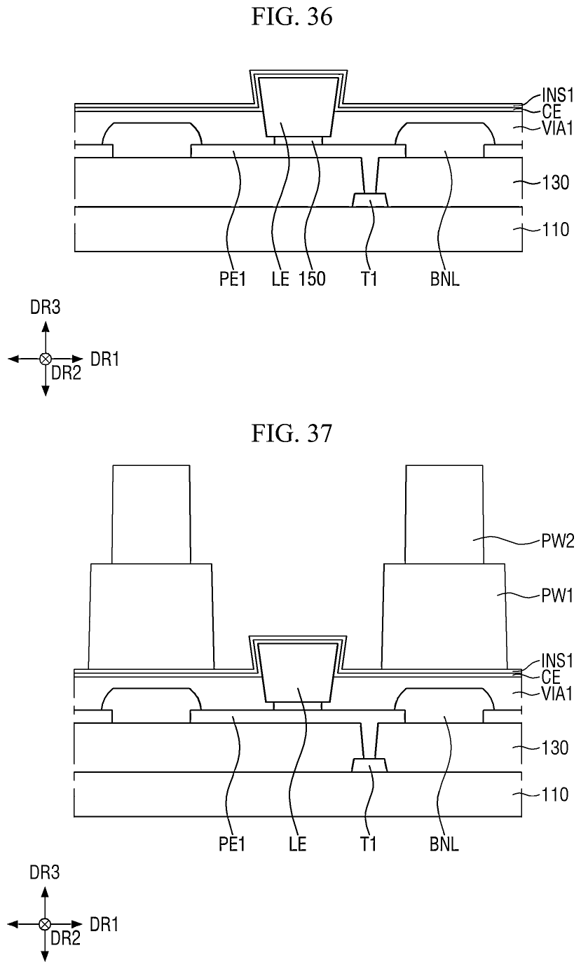

Next, referring to FIG. 36, the common electrode CE and the first insulating layer INS1 are formed on the first via layer VIA1 and the light emitting element LE.

The common electrode CE is continuously formed throughout the display area. The common electrode CE covers the first via layer VIA1 and the light emitting element LE and is in direct contact with them. The common electrode CE is formed in direct contact with the top surface and at least some of the side surfaces of the second semiconductor layer SEM2 of the light emitting element LE. The first insulating layer INS1 may be formed on the common electrode CE.

Next, referring to FIG. 37, the partition wall unit PW (see FIG. 7) is formed on the first insulating layer INS1.

Specifically, the first partition wall PW1 is formed on the first insulating layer INS1 using various materials such as polymer or photoresist (PR) material using an inkjet printing method or the like. The first partition wall PW1 is formed in the non-light emitting area NEA with a first width WH1 (see FIG. 7) in the first direction DR1. Additionally, the first partition wall PW1 is formed on the bank BNL.

Afterwards, the second partition wall PW2 is formed on the first partition wall PW1. The second partition wall PW2 is formed on the first partition wall PW1 to have a second width WH2 (see FIG. 7) in the first direction DR1. The second width WH2 may be narrower than the first width WH1.

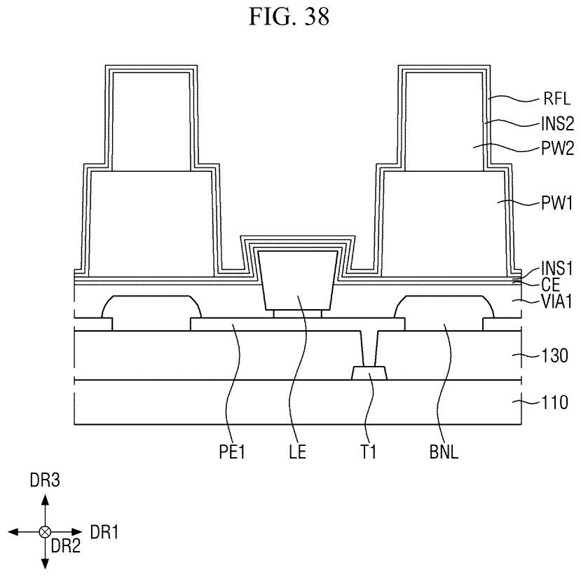

Next, referring to FIG. 38, the second insulating layer INS2 and the reflective material layer RFL are formed on the partition wall unit PW.

The second insulating layer INS2 may be formed to cover all the light emitting elements LE protruding on the first via layer VIA1 and the partition wall unit PW. Next, the reflective material layer RFL is formed on the second insulating layer INS2. The reflective material layer RFL may be formed on the second insulating layer INS2 to cover all the light emitting elements LE protruding on the first via layer VIA1 and the partition wall unit PW.

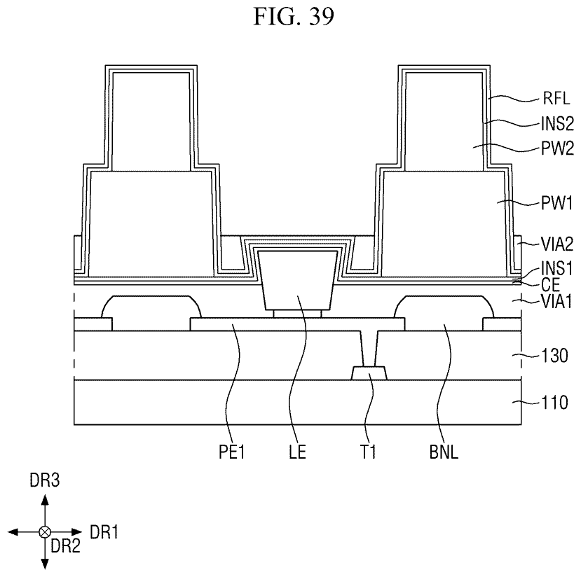

Next, referring to FIG. 39, the second via layer VIA2 is formed in the openings formed between the partition wall unit PW.

The second via layer VIA2 may be manufactured in the same manner as the first via layer VIA1 described above and may be spaced from each other between adjacent light emitting areas in each light emitting area EA1. The second via layer VIA2 may be formed to a height lower than the height of the reflective material layer RFL covering the light emitting element LE.

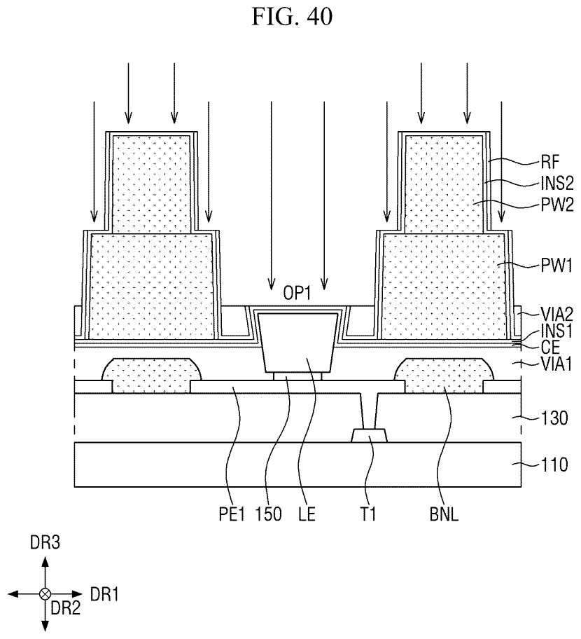

Next, referring to FIG. 40, the reflective material layer RFL is etched to form a reflective layer RF. The reflective material layer RFL may be etched using the second via layer VIA2 as a mask. A large voltage difference is formed in the third direction DR3 using the second via layer VIA2 as a mask, and the reflective material layer RFL is etched using an etching material. In this case, the etchant moves in the third direction DR3 by voltage control, i.e., moving from the top to the bottom, and may etch the reflective material layer RFL. As a result, the reflective material layer RFL disposed on the horizontal plane defined by the first direction DR1 and the second direction DR2 is removed, while the reflective material layer RFL disposed on the vertical plane defined by the third direction DR3 may not be removed. Therefore, the reflective material layer RFL formed by the step difference between the first partition wall PW1 and the second partition wall PW2 and the reflective material layer RFL formed on the light emitting element LE may be removed. The reflective material layer RFL disposed on the sides of the first partition wall PW1 and the second partition wall PW2 may not be removed. Further, the reflective material layer RFL disposed bottom of the second via layer VIA2 may not be removed.

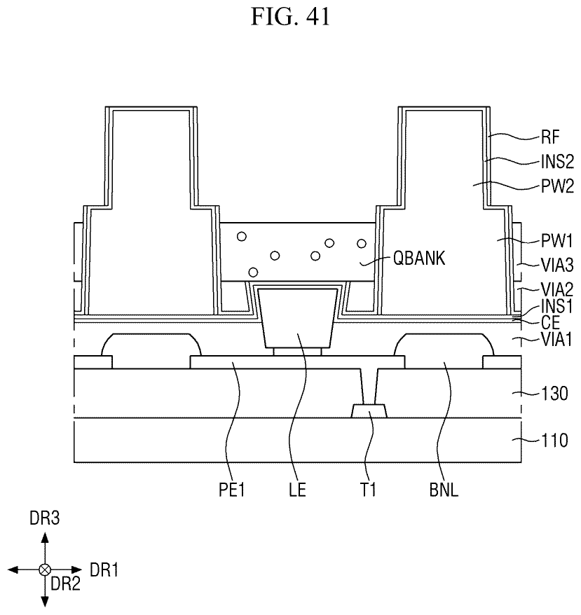

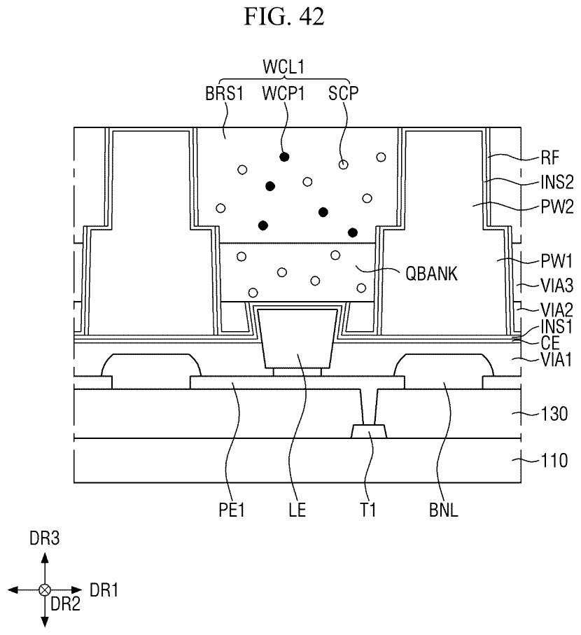

Next, referring to FIGS. 41 and 42, the deterioration prevention layer QBANK and the wavelength conversion layer QDL are formed in the openings OP1 (see FIG. 40) formed between the partition wall unit PW and the adjacent partition wall unit PW.

The deterioration prevention layer QBANK is formed on the second via layer VIA2 between the partition wall unit PW and the adjacent partition wall unit PW and the light emitting element LE and the first wavelength conversion pattern WCL1 is formed on the deterioration prevention layer QBANK.

The deterioration prevention layer QBANK may be formed by a solution process such as inkjet printing, imprinting, etc. of a solution of the scatterer SCP mixed with the third base resin BRS3 but is not limited thereto. Each of the deterioration prevention layer QBANK may be formed within a plurality of openings OP1 and may be formed to overlap with the plurality of light emitting areas. The height of the deterioration prevention layer QBANK may be formed to be lower than the height of the wavelength conversion layer QDL.

The first wavelength conversion pattern WCL1 may be formed by a solution process such as inkjet printing, imprinting, etc. of a solution containing the first base resin BRS1, the first wavelength conversion particle WCP1, and the scatterer SCP but is not limited to this. Each wavelength conversion layer QDL may be formed within the plurality of openings OP1 and may be formed to overlap the plurality of light emitting areas.

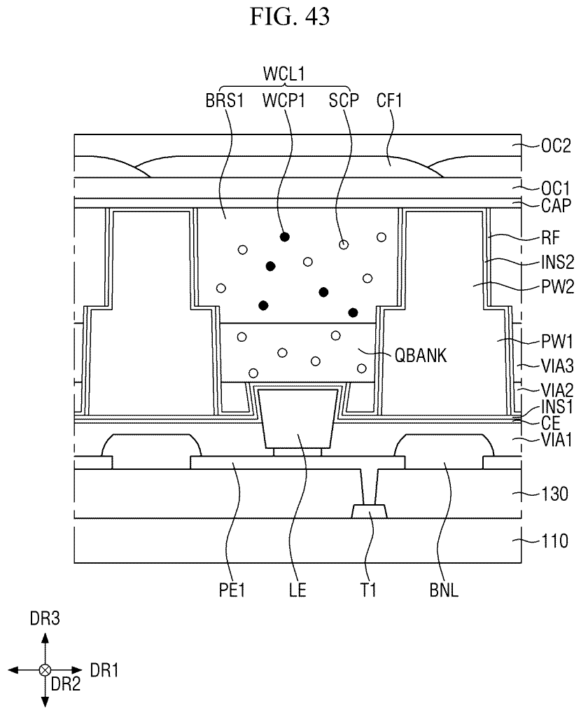

As shown in FIG. 43, the capping layer CAP, the first overcoat layer OC1, the color filter CF1, and the second overcoat layer OC2 are formed.

The color filter CF1 may be formed through a patterning process. The thickness of the color filter CF1 may be 1 μm or less but is not limited thereto. Similarly, other color filters are also formed to overlap each opening through a patterning process.

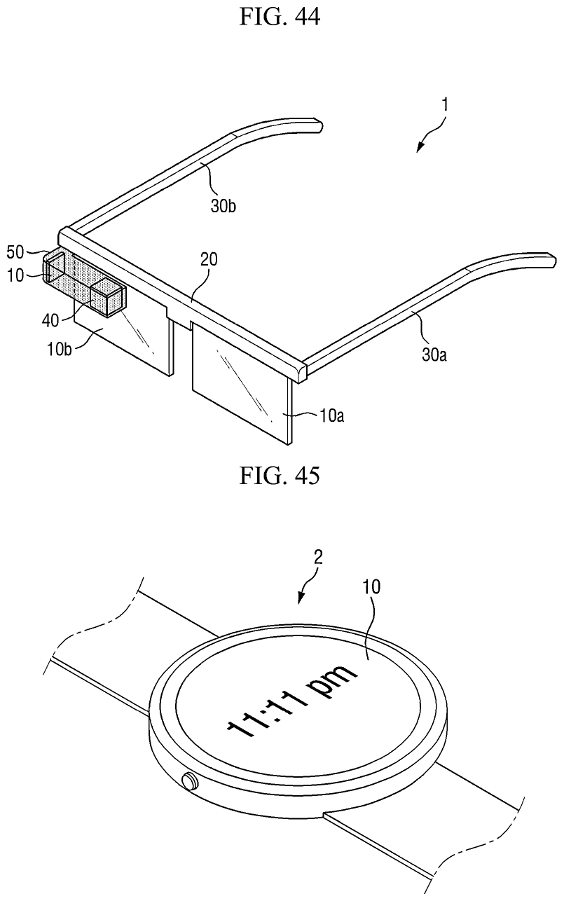

FIG. 44 is an example diagram illustrating a virtual reality device including a display device according to one or more embodiments. FIG. 44 illustrates a virtual reality device 1 in which the display device 10 according to one or more embodiments is used.

Referring to FIG. 44, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 44 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 44, and may be applied in various forms in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 44 illustrates that the display device housing 50 is disposed at a right end of the support frame 20. However, the present disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

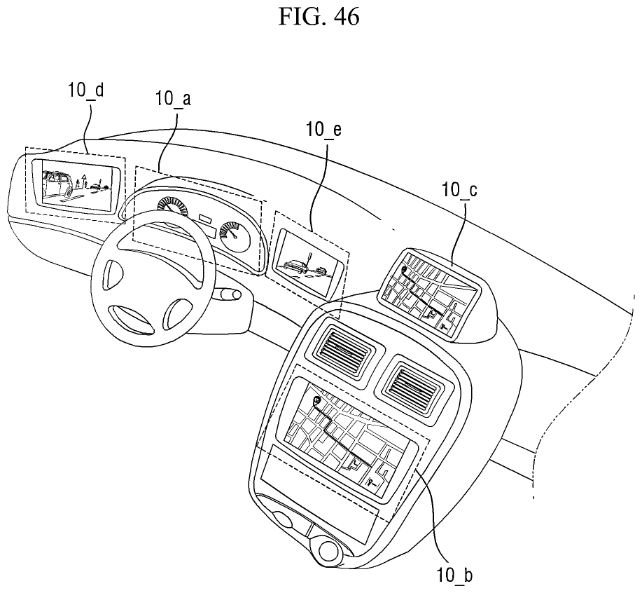

FIG. 45 is an example diagram illustrating a smart device including a display device according to one or more embodiments.

Referring to FIG. 45, a display device 10 according to one or more embodiments may be applied to a smart watch 2 as one of smart devices.

FIG. 46 is an example diagram illustrating a vehicle including a display device according to one or more embodiments. FIG. 46 illustrates a vehicle in which display devices according to one or more embodiments are used.

Referring to FIG. 46, the display devices 10_a, 10_b, and 10_c according to one or more embodiments may be applied to the dashboard of the vehicle, applied to the center fascia of the vehicle, or applied to a Center Information Display (CID) disposed on the dashboard of the vehicle. Further, each of the display devices 10_d and 10_e according to one or more embodiments may be applied to each room mirror display that replaces each of side-view mirrors of the vehicle.

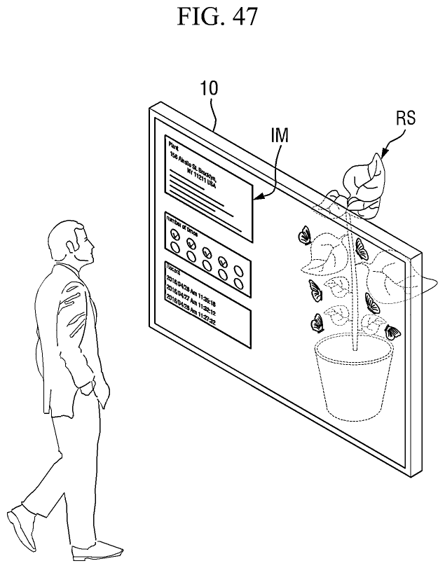

FIG. 47 is an example diagram illustrating a transparent display device including a display device according to one or more embodiments.

Referring to FIG. 47, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate 110 of the display device 10 shown in FIG. 7 may include a light transmitting portion that may transmit light therethrough or may be made of a material that may transmit light therethrough.

In concluding the detailed description, those skilled in the art will appreciate that many variations and modifications can be made to one or more embodiments without substantially departing from the principles and scope of the present disclosure. Therefore, the embodiments of the present disclosure are used in a generic and descriptive sense only and not for purposes of limitation.

Further, the aspects and features of embodiments of the disclosure are not restricted to the one set forth herein. The above and other aspects and features of embodiments of the present disclosure will become more apparent to one of daily skill in the art to which the present disclosure pertains by referencing the claims, with functional equivalents thereof to be included therein.

What is claimed is:

1. A display device comprising:
a pixel electrode on a substrate;
a bank layer on the substrate and the pixel electrode and dividing a light emitting area and a light non-emitting area;
a light emitting element on the pixel electrode and comprising a first semiconductor layer, a second semiconductor layer, and an active layer interposed between the first semiconductor layer and the second semiconductor layer;
a first via layer on the pixel electrode and around at least a portion of a side of the light emitting element;
a common electrode on the first via layer, a side of a light emitting element from protruding from the first via layer, and a top surface of the light emitting element;
a first insulating layer on the common electrode;
a partition wall unit on the first insulating layer and overlapping the bank layer;
a second insulating layer on the partition wall unit;
a reflective layer around a side of the partition wall unit on the second insulating layer and a side of the light emitting element on the first insulating layer, and on the first insulating layer between the partition wall unit and the light emitting element;
a second via layer between the partition wall units and having an opening exposing the first insulating layer on the light emitting element; and
a wavelength conversion layer on the second via layer.

2. The display device of claim 1, further comprising a deterioration prevention layer located between the second via layer and the wavelength conversion layer and comprising a base resin and a scatterer.

3. The display device of claim 2, wherein the partition wall unit comprises a first partition wall on the first insulating layer and having a first width and a second partition wall on the first partition wall and having a second width,
wherein the first width is greater than the second width.

4. The display device of claim 3, wherein the reflective layer comprises a first reflective layer around a side of the first partition wall, a second reflective layer around a side of the second partition wall, a third reflective layer around a portion of the side of the light emitting element, and a fourth reflective layer located between the first reflective layer and the third reflective layer and between the second via layer and the first insulating layer.

5. The display device of claim 4, wherein the third reflective layer is in contact with the first insulating layer and has a height equal to a height of the second via layer.

6. The display device of claim 5, wherein the third reflective layer is around at least a portion of a side surface of the second semiconductor layer of the light emitting element on the first insulating layer.

7. The display device of claim 4, wherein the first via layer covers the bank layer and a portion of the pixel electrode on which the light emitting element is not located,
wherein the second via layer covers the fourth reflective layer between the partition walls units and is around the third reflective layer.

8. The display device of claim 1, wherein the light emitting element further comprises an element insulating layer around the first semiconductor layer, the active layer, and the second semiconductor layer, and a connection electrode located between the first semiconductor layer and the pixel electrode.

9. The display device of claim 8, further comprising an element reflective layer spaced from the common electrode and around at least a portion of a side surface of the light emitting element on the element insulating layer.

10. The display device of claim 2, further comprising a capping layer, an overcoat layer, and a color filter layer sequentially arranged on the wavelength conversion layer and the partition wall unit.

11. The display device of claim 10, further comprising a touch sensing unit located between the overcoat layer and the color filter layer.

12. A display device comprising:
a first electrode and a second electrode on a substrate;
a bank layer on the substrate, the first electrode, and the second electrode, and dividing a light emitting area and a light non-emitting area;
a light emitting element comprising a first contact electrode, a second contact electrode, a first semiconductor layer on the first contact electrode, an active layer, and a second semiconductor layer on the second contact electrode and the active layer;
a first via layer on the first electrode and the second electrode and around at least a portion of a side of the light emitting element;
a first insulating layer on the first via layer, a side surface of the light emitting element protruding from the first via layer, and a top surface of the light emitting element;
a partition wall unit on the first insulating layer and overlapping the bank layer;
a second insulating layer on the partition wall unit;
a reflective layer around a side of the partition wall unit on the second insulating layer and a side of the light emitting element on the first insulating layer, and on the first insulating layer between the partition wall unit and the light emitting element;
a second via layer located between the partition wall units; and
a wavelength conversion layer on the second via layer.

13. The display device of claim 12, further comprising a deterioration prevention layer located between the second via layer and the wavelength conversion layer and including a base resin and a scatterer.

14. The display device of claim 13, wherein the partition wall unit comprises a first partition wall on the first insulating layer and having a first width and a second partition wall on the first partition wall and having a second width,
wherein the first width is greater than the second width.

15. The display device of claim 14, wherein the reflective layer comprises a first reflective layer around a side of the first partition wall, a second reflective layer around a side of the second partition wall, a third reflective layer around a portion of the side of the light emitting element, and a fourth reflective layer located between the first reflective layer and the third reflective layer and between the second via layer and the first insulating layer.

16. The display device of claim 15, wherein the third reflective layer is in contact with the first insulating layer and has a height equal to a height of the second via layer.

17. The display device of claim 16, wherein the third reflective layer is around at least a portion of a side surface of the second semiconductor layer of the light emitting element on the first insulating layer.

18. The display device of claim 15, wherein the first via layer covers the bank layer and a portion of the first electrode and the second electrode on which the light emitting element is not located,
wherein the second via layer covers the fourth reflective layer between the partition walls units and is around the third reflective layer.

19. The display device of claim 14, wherein a height of the first partition wall is greater than or equal to a height of the second partition wall.

20. The display device of claim 12, further comprising a capping layer, an overcoat layer, and a color filter layer sequentially arranged on the wavelength conversion layer and the partition wall unit.
